(19) United States
(12) Patent Application Publication
(10) Pub. No.: US 2025/0362547 A1
(43) Pub. Date: Nov. 27, 2025

(54) OPTICALLY ANISOTROPIC FILM, OPTICAL FILM, POLARIZING PLATE, AND IMAGE DISPLAY APPARATUS

(71) Applicant: FUJIFILM Corporation, Tokyo (JP)

(72) Inventors: Ayako MURAMATSU, Kanagawa (JP); Kunihiro KASEZAWA, Kanagawa (JP); Toshihiro KONISHI, Kanagawa (JP); Hiroki KUWAHARA, Kanagawa (JP)

(73) Assignee: FUJIFILM Corporation, Tokyo (JP)

(21) Appl. No.: 19/289,715

(22) Filed: Aug. 4, 2025

Related U.S. Application Data
(63) Continuation of application No. PCT/JP2024/007223, filed on Feb. 28, 2024.

(30) Foreign Application Priority Data
Mar. 20, 2023 (JP) 2023-043920

(51) Int. Cl. G02F 1/1337; G02B 5/30

(52) U.S. Cl. CPC G02F 1/133723; G02B 5/3016; G02F 1/133769; G02F 1/133788

(57) ABSTRACT

An optically anisotropic film which has excellent liquid crystal alignment properties and excellent adhesiveness with an adjacent layer, an optical film, a polarizing plate, and an image display apparatus. The optically anisotropic film is obtained by fixing an alignment state of a liquid crystal composition, in which the liquid crystal composition contains a liquid crystal compound, a fluorine-containing polymer A, and a fluorine-containing polymer B, a surface energy of a single film of the fluorine-containing polymer A is higher than a surface energy of a single film of the fluorine-containing polymer B, and an abundance ratio R(A) represented by the expression (1) R(A)=MA(5)/MA(0) and an abundance ratio R(B) represented by the expression (2) R(B)=MB(5)/MB(0) satisfy a relationship represented by the expression (3) 50≥R(A)/R(B)≥5.

### CROSS-REFERENCE TO RELATED APPLICATIONS

This application is a Continuation of PCT International Application No. PCT/JP2024/007223 filed on Feb. 28, 2024, which was published under PCT Article 21(2) in Japanese, and which claims priority under 35 U.S.C. § 119(a) to Japanese Patent Application No. 2023-043920 filed on Mar. 20, 2023. The above applications are hereby expressly incorporated by reference, in their entirety, into the present application.

### BACKGROUND OF THE INVENTION

### 1. Field of the Invention

The present invention relates an optically anisotropic film, an optical film, a polarizing plate, and an image display apparatus.

### 2. Description of the Related Art

Optical films such as optical compensation sheets and retardation films are used in various image display apparatus from the viewpoint of solving image coloration or widening a viewing angle.

A stretched birefringent film has been used as the optical film, but in recent years, it has been proposed to use a phase difference film (optically anisotropic film) formed of a liquid crystal compound instead of the stretched birefringent film.

In addition, the optical film is usually required to have a uniform thickness in a plane. In order to achieve such a uniform thickness, in a case where a substrate is coated with a liquid crystal composition, the coating is required to be made uniformly.

It has been known that a liquid crystal composition containing a surfactant is used in order to uniformly perform the coating.

For example, WO2020/067291A discloses an optically anisotropic film formed of a liquid crystal composition obtained by blending two kinds of fluorine-containing polymers with a liquid crystal compound ([0071] to [0080], and the like).

### SUMMARY OF THE INVENTION

As a result of studying the liquid crystal composition and the optically anisotropic film disclosed in WO2020/067291A and the like, the present inventors have found that there is room for improvement in liquid crystal alignment properties of the optically anisotropic film to be formed depending on the kind of the surfactant contained in the liquid crystal composition (in a case of being used in combination, the combination thereof) and there is room for improvement in adhesiveness with an adjacent layer.

Therefore, an object of the present invention is to provide an optically anisotropic film which has excellent liquid crystal alignment properties and excellent adhesiveness with an adjacent layer, an optical film, a polarizing plate, and an image display apparatus.

As a result of intensive studies to achieve the above-described object, the present inventors have found that the optically anisotropic film having excellent liquid crystal alignment properties and excellent adhesiveness with an adjacent layer can be formed by satisfying a specific relationship between a predetermined abundance ratio of a fluorine-containing polymer A and a predetermined abundance ratio of a fluorine-containing polymer B, thereby achieving the present invention.

In other words, it has been found that the above-described objects can be achieved by adopting the following configurations.

[1] An optically anisotropic film obtained by fixing an alignment state of a liquid crystal composition,
in which the liquid crystal composition contains a liquid crystal compound, a fluorine-containing polymer A, and a fluorine-containing polymer B, or contains a liquid crystal compound, a silicon-containing polymer C, and a silicon-containing polymer D,
a surface energy of a single film of the fluorine-containing polymer A is higher than a surface energy of a single film of the fluorine-containing polymer B, or a surface energy of a single film of the silicon-containing polymer C is higher than a surface energy of a single film of the silicon-containing polymer D, and
an abundance ratio R(A) represented by the following expression (1) and an abundance ratio R(B) represented by the following expression (2) satisfy a relationship represented by the following expression (3), or an abundance ratio R(C) represented by the following expression (4) and an abundance ratio R(D) represented by the following expression (5) satisfy a relationship represented by the following expression (6),

$$R ( A ) = MA ( 5 ) / MA ( 0 ) , \qquad ( 1 )$$

$$R ( B ) = MB ( 5 ) / MB ( 0 ) , \qquad ( 2 )$$

$$50 \geq R ( A ) / R ( B ) \geq 5 , \qquad ( 3 )$$

$$R ( C ) = MC ( 5 ) / MC ( 0 ) , \qquad ( 4 )$$

$$R ( D ) = MD ( 5 ) / MD ( 0 ) , \qquad ( 5 )$$

$$50 \geq R ( C ) / R ( D ) \geq 5 , \qquad ( 6 )$$

in the expression (1), MA(5) represents an amount of the fluorine-containing polymer A present at a position of 5 nm away from one surface X of the optically anisotropic film in a thickness direction, MA(0) represents an amount of the fluorine-containing polymer A present at the surface X, and MA(0) represents a value larger than MA(5),
in the expression (2), MB(5) represents an amount of the fluorine-containing polymer B present at a position of 5 nm away from the surface X in the thickness direction, MB(0) represents an amount of the fluorine-containing polymer B present at the surface X, and MB(0) represents a value larger than MB(5),
in the expression (4), MC(5) represents an amount of the silicon-containing polymer C present at a position of 5 nm away from the surface X in the thickness direction, MC(0) represents an amount of the silicon-containing polymer C present at the surface X, and MC(0) represents a value larger than MC(5),
in the expression (5), MD(5) represents an amount of the silicon-containing polymer D present at a position of 5 nm away from the surface X in the thickness direction, MD(0) represents an amount of the silicon-containing polymer D present at the surface X, and MD(0) represents a value larger than MD(5).

[2] The optically anisotropic film according to [1],
in which the liquid crystal composition contains a liquid crystal compound, a fluorine-containing polymer A, and a fluorine-containing polymer B,
a surface energy of a single film of the fluorine-containing polymer A is higher than a surface energy of a single film of the fluorine-containing polymer B, and
an abundance ratio R(A) represented by the following expression (1) and an abundance ratio R(B) represented by the following expression (2) satisfy a relationship represented by the following expression (3),

$$R ( A ) = MA ( 5 ) / MA ( 0 ) , \qquad ( 1 )$$

$$R ( B ) = MB ( 5 ) / MB ( 0 ) , \qquad ( 2 )$$

$$50 \geq R ( A ) / R ( B ) \geq 5 , \qquad ( 3 )$$

in the expression (1), MA(5) represents an amount of the fluorine-containing polymer A present at a position of 5 nm away from one surface X of the optically anisotropic film in a thickness direction, MA(0) represents an amount of the fluorine-containing polymer A present at the surface X, and MA(0) represents a value larger than MA(5),
in the expression (2), MB(5) represents an amount of the fluorine-containing polymer B present at a position of 5 nm away from the surface X in the thickness direction, MB(0) represents an amount of the fluorine-containing polymer B present at the surface X, and MB(0) represents a value larger than MB(5).

[3] The optically anisotropic film according to [1] or [2],
in which the fluorine-containing polymer B has a repeating unit including, in a side chain, at least one reactive group selected from the group consisting of an acryloyl group, a methacryloyl group, an epoxy group, and a boronic acid group.

[4] The optically anisotropic film according to any one of [1] to [3],
in which the fluorine-containing polymer A has a repeating unit including, in a side chain, at least one polar group selected from the group consisting of a hydroxyl group and a carboxylic acid group.

[5] The optically anisotropic film according to any one of [1] to [4],
in which the optically anisotropic film is a positive C-plate or a negative C-plate.

[6] The optically anisotropic film according to any one of [1] to [5],
in which both the fluorine-containing polymer A and the fluorine-containing polymer B have a repeating unit, in a side chain, an alkyl group having 1 to 20 carbon atoms in which at least one hydrogen atom is replaced with a fluorine atom, and
a number of carbon atoms in the alkyl group of the fluorine-containing polymer A is smaller than a number of carbon atoms in the alkyl group of the fluorine-containing polymer B.

[7] The optically anisotropic film according to [6],
in which the number of carbon atoms in the alkyl group of the fluorine-containing polymer A is 4 or less.

[8] The optically anisotropic film according to any one of [1] to [7],
in which a content of the fluorine-containing polymer A is higher than a content of the fluorine-containing polymer B.

[9] An optical film comprising:
the optically anisotropic film according to any one of [1] to [8].

[10] A polarizing plate comprising:
the optically anisotropic film according to any one of [1] to [8]; and a polarizer.

[11] An image display apparatus comprising:
the optically anisotropic film according to any one of [1] to [8].

[12] The optically anisotropic film according to [1],
in which the liquid crystal composition contains a liquid crystal compound, a silicon-containing polymer C, and a silicon-containing polymer D,
a surface energy of a single film of the silicon-containing polymer C is higher than a surface energy of a single film of the silicon-containing polymer D, and
an abundance ratio R(C) represented by the following expression (4) and an abundance ratio R(D) represented by the following expression (5) satisfy a relationship represented by the following expression (6),

$$R ( C ) = MC ( 5 ) / MC ( 0 ) , \qquad ( 4 )$$

$$R ( D ) = MD ( 5 ) / MD ( 0 ) , \qquad ( 5 )$$

$$50 \geq R ( C ) / R ( D ) \geq 5 , \qquad ( 6 )$$

in the expression (4), MC(5) represents an amount of the silicon-containing polymer C present at a position of 5 nm away from one surface X of the optically anisotropic film in a thickness direction, MC(0) represents an amount of the silicon-containing polymer C present at the surface X, and MC(0) represents a value larger than MC(5),
in the expression (5), MD(5) represents an amount of the silicon-containing polymer D present at a position of 5 nm away from the surface X in the thickness direction, MD(0) represents an amount of the silicon-containing polymer D present at the surface X, and MD(0) represents a value larger than MD(5).

[13] The optically anisotropic film according to [12],
in which the silicon-containing polymer D has a repeating unit including, in a side chain, at least one reactive group selected from the group consisting of an acryloyl group, a methacryloyl group, an epoxy group, and a boronic acid group.

[14] The optically anisotropic film according to or [12] or [13],
in which the optically anisotropic film is a positive C-plate or a negative C-plate.

[15] The optically anisotropic film according to any one of to [12] to [14],
in which a content of the silicon-containing polymer C is higher than a content of the silicon-containing polymer D.

[16] An optical film comprising:
the optically anisotropic film according to any one of to [12] to [15].

[17] A polarizing plate comprising:
the optically anisotropic film according to any one of to [12] to [15]; and a polarizer.

[18] An image display apparatus comprising:
the optically anisotropic film according to any one of [12] to [15].

According to the present invention, it is possible to provide an optically anisotropic film which has excellent liquid crystal alignment properties and excellent adhesiveness with an adjacent layer, an optical film, a polarizing plate, and an image display apparatus.

### BRIEF DESCRIPTION OF THE DRAWINGS

FIG. 1 is a schematic cross-sectional view showing an example of an optical film.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

Any numerical range expressed using “to” in the present specification refers to a range including the numerical values before and after the “to” as a lower limit value and an upper limit value, respectively.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, substances corresponding to respective components may be used alone or in combination of two or more kinds thereof. Here, in a case where two or more types of substances are used in combination for each component, the content of the component refers to a total content of the substances used in combination unless otherwise specified.

In addition, in this specification, “(meth)acrylic” is a notation representing “acrylic” or “methacrylic”.

In addition, in the present specification, a bonding direction of a divalent group (for example, —O—CO—) described is not particularly limited, and for example, in a case where L² in an “L¹-L²-L³” bond is —O—CO—, and a bonding position on the L¹ side is represented by *1 and a bonding position on the L³ side is represented by *2, L² may be *1—O—CO—*2 or *1—CO—O—*2.

In the present specification, Re(λ) and Rth(λ) respectively represent an in-plane retardation at a wavelength λ and a thickness-direction retardation at a wavelength λ. Unless otherwise specified, the wavelength λ refers to 550 nm.

In addition, in the present specification, Re(λ) and Rth(λ) are values measured at a wavelength λ using AxoScan OPMF-1 (manufactured by Optoscience. Inc.).

Specifically, by inputting an average refractive index ((nx+ny+nz)/3) and a film thickness (d (μm)) in AxoScan OPMF-1, a slow axis direction) (°), Re(λ)=R0(λ), and Rth(λ) =((nx+ny)/2−nz)×d are calculated.

In addition, R0(λ) is expressed in a numerical value calculated with AxoScan OPMF-1, and means Re(λ).

### Optically Anisotropic Film

The optically anisotropic film according to a first aspect of the present invention is an optically anisotropic film obtained by fixing an alignment state of a liquid crystal composition.

In the optically anisotropic film according to the first aspect of the present invention, the above-described liquid crystal composition contains a liquid crystal compound, a fluorine-containing polymer A, and a fluorine-containing polymer B, a surface energy of a single film of the fluorine-containing polymer A is higher than a surface energy of a single film of the fluorine-containing polymer B, and an abundance ratio R(A) represented by the following expression (1) and an abundance ratio R(B) represented by the following expression (2) satisfy a relationship represented by the following expression (3).

In a case where the above-described liquid crystal composition contains three or more kinds of fluorine-containing polymers, any two kinds of fluorine-containing polymers, that is, any two kinds of fluorine-containing polymers classified as the fluorine-containing polymer A and the fluorine-containing polymer B from the magnitude relationship of the surface energy of the single film may satisfy the relationship represented by the expression (3).

$$R ( A ) = MA ( 5 ) / MA ( 0 ) \qquad ( 1 )$$

$$R ( B ) = MB ( 5 ) / MB ( 0 ) \qquad ( 2 )$$

$$50 \geq R ( A ) / R ( B ) \geq 5 \qquad ( 3 )$$

In the expression (1), MA(5) represents an amount of the fluorine-containing polymer A present at a position of 5 nm away from one surface X of the optically anisotropic film in a thickness direction, MA(0) represents an amount of the fluorine-containing polymer A present at the surface X, and MA(0) represents a value larger than MA(5).

In the expression (2), MB(5) represents an amount of the fluorine-containing polymer B present at a position of 5 nm away from the surface X in the thickness direction, MB(0) represents an amount of the fluorine-containing polymer B present at the surface X, and MB(0) represents a value larger than MB(5).

In the first aspect of the present invention, the abundance ratio R(A) represented by the expression (1) and the abundance ratio R(B) represented by the expression (2) preferably satisfy a relationship represented by the following expression (3-1), and more preferably satisfy a relationship represented by the following expression (3-2).

$$45 \geq R ( A ) / R ( B ) \geq 10 \qquad ( 3 - 1 )$$

$$30 \geq R ( A ) / R ( B ) \geq 15 \qquad ( 3 - 2 )$$

Here, the abundance ratio R(A) represented by the expression (1) and the abundance ratio R(B) represented by the expression (2) refer to values measured by the following method using time-of-flight secondary ion mass spectrometry (TOF-SIMS).

A range of 900 μm² of one surface X of the optically anisotropic film to be measured is analyzed by TOF-SIMS (TOF-SIMS5, manufactured by IONTOF GmbH) while etching using Ar-GCIB.

Specifically, for the abundance ratio R(A), a secondary ion intensity of a fragment corresponding to ions derived from the fluorine-containing polymer A (for example, C₅F₇⁻) on a surface of 900 μm² (that is, the outermost surface which has not been subjected to etching) and a surface of 900 μm² exposed by performing the etching to a depth position of 5 nm away from the surface X in the thickness direction is measured, and the abundance ratio R(A) is calculated from an intensity ratio thereof (5 nm position/surface X).

Similarly, for the abundance ratio R(B), a secondary ion intensity of a fragment corresponding to ions derived from the fluorine-containing polymer B (for example, C₇F₁₁⁻) on a surface of 900 μm² (that is, the outermost surface which has not been subjected to etching) and a surface of 900 μm² exposed by performing the etching to a depth position of 5 nm away from the surface X in the thickness direction is measured, and the abundance ratio R(B) is calculated from an intensity ratio thereof (5 nm position/surface X).

The optically anisotropic film according to a second aspect of the present invention is an optically anisotropic film obtained by fixing an alignment state of a liquid crystal composition.

In the optically anisotropic film according to the second aspect of the present invention, the above-described liquid crystal composition contains a liquid crystal compound, a silicon-containing polymer C, and a silicon-containing polymer D, a surface energy of a single film of the silicon-containing polymer C is higher than a surface energy of a single film of the silicon-containing polymer D, and an abundance ratio R(C) represented by the following expression (4) and an abundance ratio R(D) represented by the following expression (5) satisfy a relationship represented by the following expression (6).

In a case where the above-described liquid crystal composition contains three or more kinds of silicon-containing polymers, any two kinds of silicon-containing polymers, that is, any two kinds of silicon-containing polymers classified as the silicon-containing polymer C and the silicon-containing polymer D from the magnitude relationship of the surface energy of the single film may satisfy the relationship represented by the expression (6).

$$R ( C ) = MC ( 5 ) / MC ( 0 ) \qquad ( 4 )$$

$$R ( D ) = MD ( 5 ) / MD ( 0 ) \qquad ( 5 )$$

$$50 \geq R ( C ) / R ( D ) \geq 5 \qquad ( 6 )$$

In the expression (4), MC(5) represents an amount of the silicon-containing polymer C present at a position of 5 nm away from one surface X of the optically anisotropic film in a thickness direction, MC(0) represents an amount of the silicon-containing polymer C present at the surface X, and MC(0) represents a value larger than MC(5).

In the expression (5), MD(5) represents an amount of the silicon-containing polymer D present at a position of 5 nm away from the surface X in the thickness direction, MD(0) represents an amount of the silicon-containing polymer D present at the surface X, and MD(0) represents a value larger than MD(5).

In the second aspect of the present invention, the abundance ratio R(C) represented by the expression (4) and the abundance ratio R(D) represented by the expression (5) preferably satisfy a relationship represented by the following expression (6-1), and more preferably satisfy a relationship represented by the following expression (6-2).

$$45 \geq R ( C ) / R ( D ) \geq 10 \qquad ( 6 - 1 )$$

$$30 \geq R ( C ) / R ( D ) \geq 15 \qquad ( 6 - 2 )$$

Here, the abundance ratio R(C) represented by the expression (4) and the abundance ratio R(D) represented by the expression (5) refer to values measured by the same method as that of the first aspect using TOF-SIMS.

In the present invention, as described above, since the abundance ratio R(A) of the fluorine-containing polymer A and the abundance ratio R(B) of the fluorine-containing polymer B satisfy the relationship represented by the expression (3), or the abundance ratio R(C) of the silicon-containing polymer C and the abundance ratio R(D) of the silicon-containing polymer D satisfy the relationship represented by the expression (6), an optically anisotropic film having excellent liquid crystal alignment properties and excellent adhesiveness with an adjacent layer can be formed.

The details of the reason for this are not clear, but the present inventors presumed the reason to be as follows.

That is, it is considered that, in the fluorine-containing polymers A and B, the fluorine-containing polymer A having a higher surface energy in the single film is present inside the optically anisotropic film and interacts with the liquid crystal compound, and the fluorine-containing polymer B having a lower surface energy in the single film interacts with the adjacent layer in the vicinity of the surface of the optically anisotropic film, so that the optically anisotropic film having excellent liquid crystal alignment properties and excellent adhesiveness with the adjacent layer can be formed. The same applies to the silicon-containing polymers C and D.

Hereinafter, each component of the liquid crystal composition before the alignment state is fixed will be described in detail regarding the optically anisotropic film according to the first aspect and the second aspect of the present invention (hereinafter, in a case where a particular distinction is not necessary, abbreviated as “optically anisotropic film according to the embodiment of the present invention”).

### Liquid Crystal Compound

The liquid crystal compound contained in the liquid crystal composition is not particularly limited.

The type of the liquid crystal compound contained in the liquid crystal composition is not particularly limited.

Here, in general, the liquid crystal compound can be classified into a rod-like type and a disk-like type according to the shape thereof. Each of the types can further be classified into a low-molecular-weight type and a high-molecular-weight type. The term “high-molecular-weight” generally refers to a compound having a degree of polymerization of 100 or more (Polymer Physics-Phase Transition Dynamics, written by Masao Doi, p. 2, published by Iwanami Shoten, 1992).

In the present invention, any liquid crystal compound can be used, and it is preferable to use a rod-like liquid crystal compound or a disk-like liquid crystal compound (discotic liquid crystal compound). A mixture of two or more kinds of the rod-like liquid crystal compounds, a mixture of two or more kinds of the disk-like liquid crystal compounds, or a mixture of the rod-like liquid crystal compound and the disk-like liquid crystal compound may be used.

The liquid crystal compound is preferably a polymerizable liquid crystal compound having a polymerizable group.

The polymerizable liquid crystal compound is preferably at least one polymerizable liquid crystal compound selected from the group consisting of a polymerizable rod-like liquid crystal compound and a polymerizable disk-like liquid crystal compound.

Examples of the polymerizable group include an acryloyl group, a methacryloyl group, an epoxy group, and a vinyl group.

By polymerizing the liquid crystal compound having such a polymerizable group, the alignment of the liquid crystal compound can be fixed. After immobilizing the liquid crystal compound by polymerization, it is no longer necessary to exhibit liquid crystallinity.

As the rod-like liquid crystal compound, for example, those described in claim 1 of JP1999-513019A (JP-H11-513019A) or paragraphs [0026] to [0098] of JP2005-289980A are preferable; and as the disk-like liquid crystal compound, those described in paragraphs [0020] to [0067] of JP2007-108732A or paragraphs [0013] to [0108] of JP2010-244038A are preferable.

In addition, a liquid crystal compound having reverse wavelength dispersibility may be used as the liquid crystal compound.

### Fluorine-Containing Polymer

The fluorine-containing polymers A and B are not particularly limited as long as they are two kinds of fluorine-containing polymers having different surface energies of single films, and the surface energy of the single film of the fluorine-containing polymer A is higher than the surface energy of the single film of the fluorine-containing polymer B.

Here, the magnitude relationship of the surface energy of the fluorine-containing polymer in the single film can be determined by the following method.

First, the fluorine-containing polymer is diluted with methyl ethyl ketone (MEK) to be 0.4%.

Next, the diluted fluorine-containing polymer solution is applied onto a cellulose-based polymer film (ZRD40, manufactured by FUJIFILM Corporation) with a spin coater (3,000 rpm), and dried on a hot plate at 70° C. for 1 minute to form a single film.

Next, contact angles of a surface of the formed single film with respect to pure water and diiodomethane are measured, and the surface energy is calculated by substituting the measured values into the equation of the surface energy of Owens.

It is preferable that both the fluorine-containing polymer A and the fluorine-containing polymer B have a repeating unit F including, in a side chain, an alkyl group having 1 to 20 carbon atoms in which at least one hydrogen atom is replaced with a fluorine atom (hereinafter, also abbreviated as “fluoroalkyl group”).

Here, the number of carbon atoms in the fluoroalkyl group refers to the number of carbon atoms in which at least one hydrogen atom is replaced with a fluorine atom. That is, for example, in a case of a group of -(CH₂)₂-(CF₂)₃-CF₃, the number of carbon atoms in the fluoroalkyl group is 4.

A structure of a main chain of the repeating unit F is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable.

Among these, a skeleton selected from the group consisting of a (meth)acrylic skeleton, a siloxane-based skeleton, and a cycloolefin-based skeleton is more preferable, and a (meth)acrylic skeleton is still more preferable.

From the reason that the liquid crystal alignment properties are further improved, the repeating unit F is preferably a repeating unit represented by Formula (F).

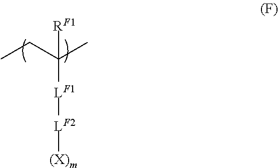

In Formula (F), R^{F1} represents a hydrogen atom or a substituent.
In addition, L^{F1} represents a single bond or a divalent linking group.
In addition, L^{F2} represents a single bond or an (m+1)-valent linking group.
In addition, X represents a fluoroalkyl group.
m represents an integer of 1 to 8. Here, in a case where m is an integer of 2 to 8, a plurality of X's may be the same or different from each other.

m in Formula (F) is preferably an integer of 1 to 4, more preferably 1 or 2, and still more preferably 1.

As described above, since L^{F1} represents a single bond or a divalent linking group, in a case where L^{F2} represents a single bond, m is 1.

The type of the substituent represented by one aspect of R^{F1} in Formula (F) is not particularly limited, and examples thereof include known substituents.

Examples of the substituent include a halogen atom, an alkyl group, an alkoxy group, an aryl group, an aryloxy group, a cyano group, a carboxy group, an alkoxycarbonyl group, and a hydroxyl group.

Examples of the halogen atom include a fluorine atom, a chlorine atom, a bromine atom, and an iodine atom, and a fluorine atom or a chlorine atom is preferable.

As the alkyl group, for example, a linear alkyl group having 1 to 18 carbon atoms or a branched or cyclic alkyl group having 3 to 18 carbon atoms is preferable, a linear alkyl group having 1 to 4 carbon atoms is more preferable, and a methyl group or an ethyl group is still more preferable.

As the alkoxy group, for example, an alkoxy group having 1 to 18 carbon atoms is preferable, an alkoxy group having 1 to 4 carbon atoms is more preferable, and a methoxy group or an ethoxy group is still more preferable.

Examples of the aryl group include an aryl group having 6 to 12 carbon atoms, and examples thereof include a phenyl group, an a-methylphenyl group, and a naphthyl group. Among these, a phenyl group is preferable.

Examples of the aryloxy group include a phenoxy group, a naphthoxy group, an imidazoyloxy group, a benzimidazoyloxy group, a pyridine-4-yloxy group, a pyrimidinyloxy group, a quinazolinyloxy group, a purinyloxy group, and a thiophen-3-yloxy group.

Examples of the alkoxycarbonyl group include a methoxycarbonyl group and an ethoxycarbonyl group.

R^{F1} is preferably a hydrogen atom or an alkyl group, and more preferably a hydrogen atom or a methyl group.

Examples of the divalent linking group represented by one aspect of L^{F1} in Formula (F) include —CO—, —O—, —S—, —C(═S)—, —CR¹R²—, —CR³═CR⁴—, —NR⁵—, and a divalent linking group consisting of a combination of two or more of these groups. R¹ to R⁵ each independently represent a hydrogen atom, a fluorine atom, or an alkyl group having 1 to 12 carbon atoms.

Among these divalent linking groups, —O—, —S—, —CO—O—, —CO—NR⁵—, or —CO—S— is preferable, and —CO—O— or —CO—NR⁵— is more preferable.

Examples of the (m+1)-valent linking group represented by one aspect of L^{F2} in Formula (F) include an alkylene group, an ether group (—O—), a ketone group (—C(═O)—), a phenylene group, a thioether group (—S—), a tertiary carbon atom, a quaternary carbon atom, and a linking group consisting of a combination thereof.

In addition, in a case where m in Formula (F) is 1, L^{F2} is preferably an alkylene group, more preferably an alkylene group having 1 to 8 carbon atoms, and still more preferably an alkylene group having 1 to 4 carbon atoms.

As described above, the fluoroalkyl group represented by X in Formula (F) is an alkyl group having 1 to 20 carbon atoms in which at least one hydrogen atom is replaced with a fluorine atom.

In the present invention, from the reason that the liquid crystal alignment properties are further improved, it is preferable that the number of carbon atoms in the fluoroalkyl group of the fluorine-containing polymer A is smaller than the number of carbon atoms in the fluoroalkyl group of the fluorine-containing polymer B.

Specifically, it is more preferable that the number of carbon atoms in the fluoroalkyl group of the fluorine-containing polymer A is 4 or less and the number of carbon atoms in the fluoroalkyl group of the fluorine-containing polymer B is 6 or more.

In a case where the fluorine-containing polymer A and the fluorine-containing polymer B contain the above-described repeating unit F, a content of the above-described repeating unit F is preferably 10% to 50% by mass, more preferably 15% to 45% by mass, and still more preferably 20% to 40% by mass with respect to the total mass of all repeating units of each fluorine-containing polymer.

In the present invention, from the reason that the liquid crystal alignment properties are further improved, it is preferable that the fluorine-containing polymer A has a repeating unit P including, in a side chain, at least one polar group selected from the group consisting of a hydroxyl group and a carboxylic acid group.

A structure of a main chain of the repeating unit P is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable.

Among these, a skeleton selected from the group consisting of a (meth)acrylic skeleton, a siloxane-based skeleton, and a cycloolefin-based skeleton is more preferable, and a (meth)acrylic skeleton is still more preferable.

From the reason that the liquid crystal alignment properties are further improved, the repeating unit P is preferably a repeating unit represented by Formula (P).

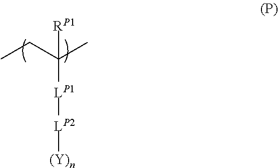

In Formula (P), R^{P1} represents a hydrogen atom or a substituent.
In addition, L^{P1} represents a single bond or a divalent linking group.
In addition, L^{P2} represents a single bond or an (n+1)-valent linking group.
In addition, Y represents at least one polar group selected from the group consisting of a hydroxyl group and a carboxylic acid group.
n represents an integer of 1 to 8. Here, in a case where n is an integer of 2 to 8, a plurality of Y's may be the same or different from each other.

Examples of the substituent represented by one aspect of R^{P1} in Formula (P), the divalent linking group represented by one aspect of L^{P1} in Formula (P), and the (n+1)-valent linking group represented by one aspect of L^{P2} in Formula (P) include the same groups as those described for the substituent represented by one aspect of R^{F1} in Formula (F), the divalent linking group represented by one aspect of L^{F1} in Formula (F), and the (m+1)-valent linking group represented by one aspect of L^{F2} in Formula (F).
In addition, n in Formula (P) is preferably an integer of 1 to 4, more preferably 1 or 2, and still more preferably 1.
In addition, L^{P1} in Formula (P) is preferably a single bond.
In addition, L^{P2} in Formula (P) is preferably a single bond.
In addition, Y in Formula (P) is preferably a carboxylic acid group (—COOH).

In a case where the fluorine-containing polymer A contains the above-described repeating unit P, a content of the above-described repeating unit F is preferably 1% to 30% by mass, more preferably 5% to 25% by mass, and still more preferably 10% to 20% by mass with respect to the total mass of all repeating units.

In the present invention, from the reason that the adhesiveness is further improved, it is preferable that the fluorine-containing polymer B has a repeating unit C including, in a side chain, at least one reactive group selected from the group consisting of an acryloyl group, a methacryloyl group, an epoxy group, and a boronic acid group.

A structure of a main chain of the repeating unit C is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable.

Among these, a skeleton selected from the group consisting of a (meth)acrylic skeleton, a siloxane-based skeleton, and a cycloolefin-based skeleton is more preferable, and a (meth)acrylic skeleton is still more preferable.

From the reason that the liquid crystal alignment properties are further improved, the repeating unit C is preferably a repeating unit represented by Formula (C).

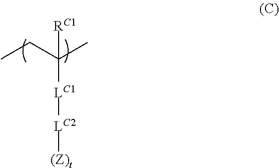

In Formula (C), R^{C1} represents a hydrogen atom or a substituent.
In addition, L^{C1} represents a single bond or a divalent linking group.
In addition, L^{C2} represents a single bond or a (t+1)-valent linking group.
In addition, Z represents at least one reactive group selected from the group consisting of an acryloyl group, a methacryloyl group, an epoxy group, and a boronic acid group.
t represents an integer of 1 to 8. Here, in a case where t is an integer of 2 to 8, a plurality of Z's may be the same or different from each other.

Examples of the substituent represented by one aspect of R^{C1} in Formula (C), the divalent linking group represented by one aspect of L^{C1} in Formula (C), and the (t+1)-valent linking group represented by one aspect of L^{C2} in Formula (C) include the same groups as those described for the substituent represented by one aspect of R^{F1} in Formula (F), the divalent linking group represented by one aspect of L^{F1} in Formula (F), and the (m+1)-valent linking group represented by one aspect of L^{F2} in Formula (F).

In addition, t in Formula (C) is preferably an integer of 1 to 4, more preferably 1 or 2, and still more preferably 1.

In addition, L^{C1} in Formula (C) is preferably a divalent linking group, more preferably —O—, —S—, —CO—O—, —CO—NR⁵—, or —CO—S—, and still more preferably —CO—O—or —CO—NR⁵—. R⁵ represents a hydrogen atom, a fluorine atom, or an alkyl group having 1 to 12 carbon atoms.

In addition, L^{C2} in Formula (C) is preferably a divalent linking group, and more preferably an alkylene group, an ether group (—O—), a ketone group (—C(═O)—), a phenylene group, or a linking group consisting of a combination of these groups.

In addition, Z in Formula (C) is preferably at least one reactive group selected from the group consisting of an acryloyl group, a methacryloyl group, and a boronic acid group.

In a case where the fluorine-containing polymer B contains the above-described repeating unit C, a content of the above-described repeating unit C is preferably 1% to 40% by mass, more preferably 5% to 35% by mass, and still more preferably 10% to 30% by mass with respect to the total mass of all repeating units.

In the present invention, from the reason that the fluorine-containing polymer A is more broadly unevenly distributed in the film thickness direction than the fluorine-containing polymer B, it is preferable that a content of the fluorine-containing polymer A is higher than a content of the fluorine-containing polymer B.

Here, the content of the fluorine-containing polymer A is preferably 0.1% to 10% by mass and more preferably 0.5% to 3% by mass with respect to the total solid content (100% by mass) of the liquid crystal composition.

In addition, the content of the fluorine-containing polymer B is preferably 0.01% to 3% by mass and more preferably 0.05% to 1% by mass with respect to the total solid content (100% by mass) of the liquid crystal composition.

### Silicon-Containing Polymer

The silicon-containing polymers C and D are not particularly limited as long as they are two kinds of silicon-containing polymers having different surface energies of single films, and the surface energy of the single film of the silicon-containing polymer C is higher than the surface energy of the single film of the silicon-containing polymer D.

Here, the magnitude relationship of the surface energy of the silicon-containing polymer in the single film can be determined by the same method as the above-described magnitude relationship of the surface energy of the fluorine-containing polymer in the single film.

The silicon-containing polymer is preferably a polymer having a repeating unit S containing a silicon atom. The repeating unit S is a repeating unit containing a silicon atom.

The number of silicon atoms contained in the repeating unit S is 1 or more, preferably 2 or more, more preferably 3 to 6, and still more preferably 3 to 5.

A structure of a main chain of the repeating unit S is not particularly limited, and examples thereof include known structures. For example, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable.

Among these, a skeleton selected from the group consisting of a (meth)acrylic skeleton, a siloxane-based skeleton, and a cycloolefin-based skeleton is more preferable, and a (meth)acrylic skeleton is still more preferable.

From the reason that the liquid crystal alignment properties are further improved, the repeating unit S is preferably a repeating unit represented by Formula (a1).

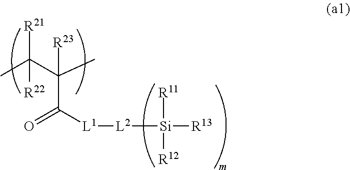

In Formula (a1), m represents an integer of 1 or more. m is preferably an integer of 3 or more, more preferably an integer of 3 to 6, and still more preferably an integer of 3 to 5.

In Formula (a1), R¹¹, R¹², and R¹³ each independently represent an alkyl group, an alkenyl group, an aryl group, or an alkylene aryl group, which may have a substituent. In a case where a plurality of R¹¹'s, R¹²'s, or R¹³'s are present, the plurality of R¹¹'s, R¹²'s, or R¹³'s may be the same or different from each other.

In Formula (a1), R²¹ and R²² each independently represent a hydrogen atom or an alkyl group.

Examples of the above-described alkyl group include a linear alkyl group having 1 to 18 carbon atoms and a branched or cyclic alkyl group having 3 to 18 carbon atoms. R²¹ and R²² are preferably a hydrogen atom.

In Formula (a1), R²³ represents a hydrogen atom or a substituent.

Examples of the above-described substituent include a substituent having an alkyl group, an alkenyl group, an aryl group, or a linking group and containing a silicon atom. The substituent having a linking group and containing a silicon atom also includes 'CH₂—CO—L¹—L²—(Si(R¹¹)(R¹²)(R¹³))ₘ. L¹, L², R¹¹, R¹², R¹³, and m are each the same as the definitions of the symbols in Formula (a1).

R²³ is preferably a hydrogen atom or an alkyl group, more preferably a hydrogen atom or a linear alkyl group having 1 to 4 carbon atoms, still more preferably a hydrogen atom, a methyl group, or an ethyl group, and particularly preferably a hydrogen atom or a methyl group.

In Formula (a1), L¹ represents —O—or NR^{Z}-. R^{Z} represents a hydrogen atom or an alkyl group (preferably, an alkyl group having 1 to 4 carbon atoms).

As L¹, —O—or NH— is preferable, and —O— is more preferable.

In Formula (a1), L² represents an (m+1)-valent linking group.

Suitable examples of the above-described (m+1)-valent linking group include an (m+1)-valent hydrocarbon group having 1 to 10 carbon atoms, which may have a substituent, in which a part of carbon atoms constituting the hydrocarbon group may be replaced with a heteroatom.

As the substituent which may be included in the above-described hydrocarbon group, an alkyl group is preferable, a linear alkyl group having 1 to 4 carbon atoms is more preferable, and a methyl group or an ethyl group is still more preferable.

Examples of the heteroatom which may replace a part of the above-described carbon atoms include a silicon atom, an oxygen atom, and a nitrogen atom.

Examples of L² include a group represented by Structural Formula K-1-L, a group represented by Structural Formula K-2-L, and a group represented by Structural Formula K-3-L. In the following structural formulae, * represents a bonding position with L¹ in Formula (a1), and ** represents a bonding position with the group represented by —SiR¹¹R¹²R¹³ in Formula (a1).

Among these, L² is preferably the group represented by Structural Formula K-1-L.

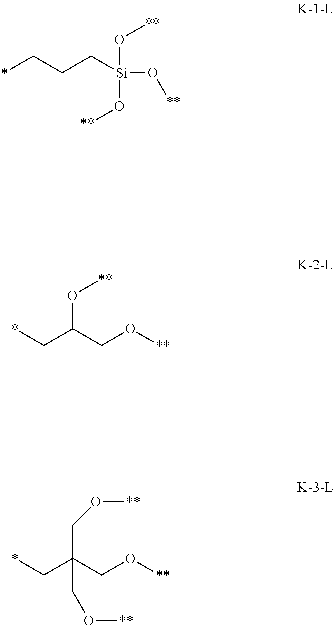

Specific examples of the repeating unit S include repeating units derived from monomers represented by K-1 to K-23. nBu represents an n-butyl group.

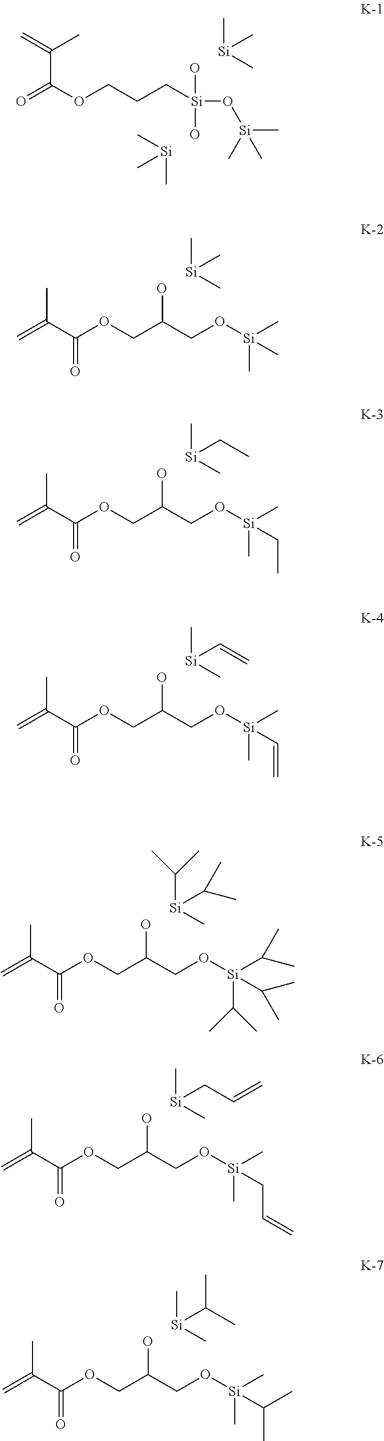

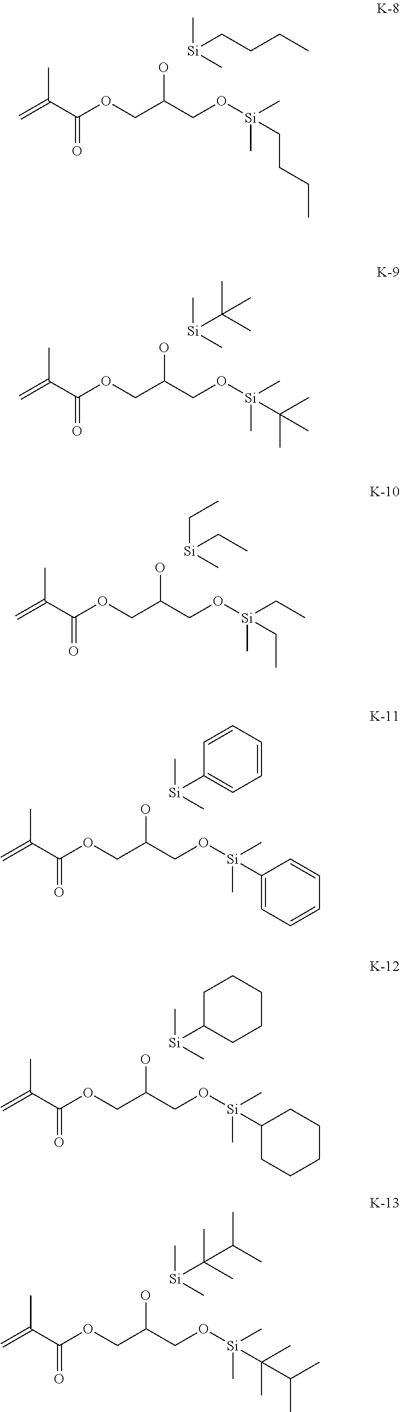

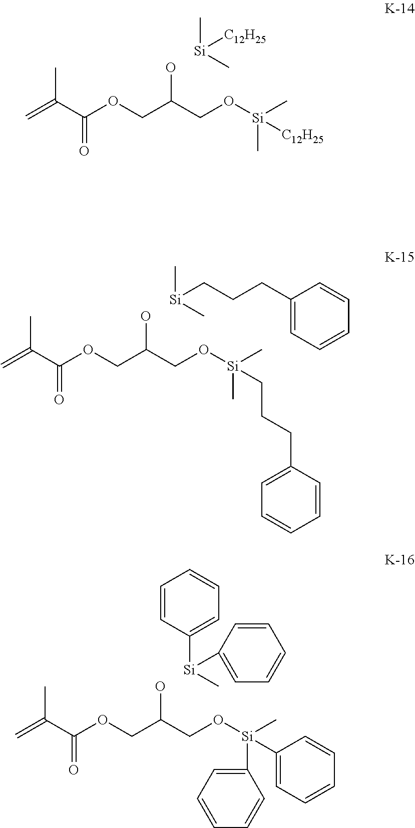

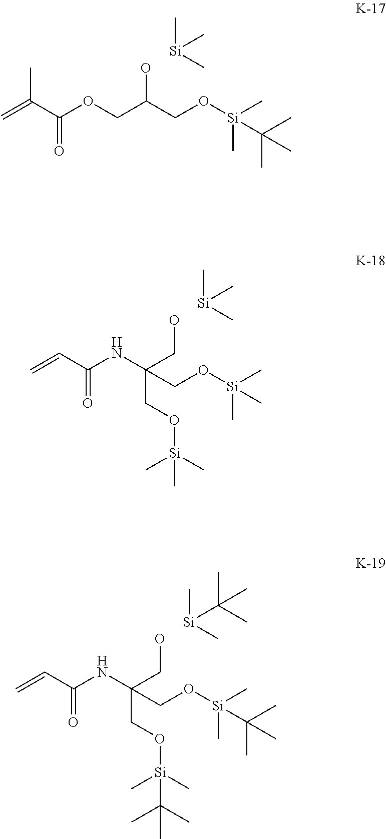

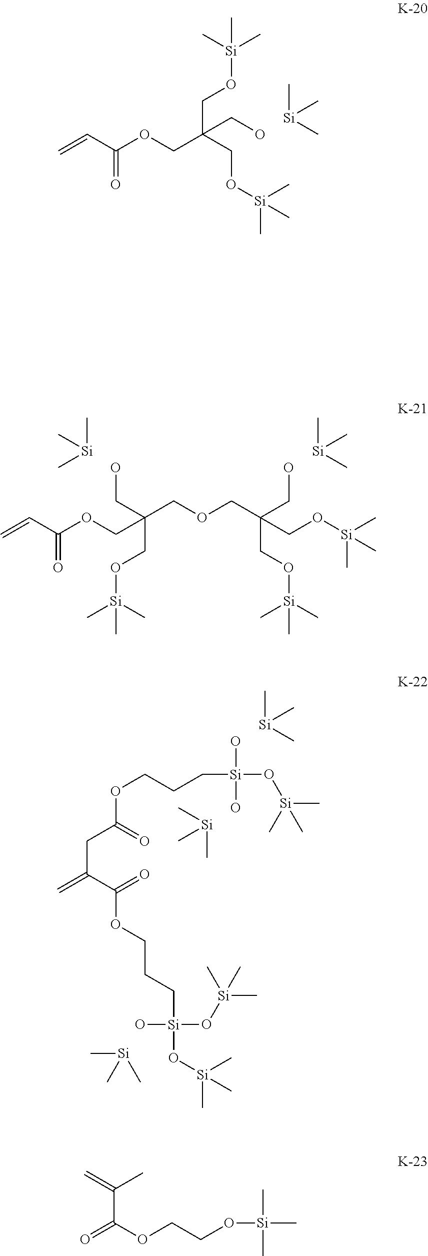

The silicon-containing polymer may have a repeating unit other than the repeating unit S.

For example, the above-described repeating unit P or repeating unit C may be further included.

A content of the repeating unit S in the silicon-containing polymer is preferably 10% to 50% by mass, more preferably 15% to 45% by mass, and still more preferably 20% to 40% by mass with respect to the total mass of all repeating units of the silicon-containing polymer.

In addition, in the present invention, weight-average molecular weights (Mw) of the fluorine-containing polymers A and B, and the silicon-containing polymer C and the silicon-containing polymer D are not particularly limited, but are preferably 5,000 to 100,000 and more preferably 8,000 to 50,000.

Here, the weight-average molecular weight in the present invention is a value measured by gel permeation chromatography (GPC).
Solvent (eluent): tetrahydrofuran
Apparatus name: EcoSEC HLC-8320GPC (manufactured by TOSOH Corporation)
Column: three columns of TSKgel SuperHZM-H, TSKgel SuperHZ4000, and TSKgel SuperHZ200 (all manufactured by TOSOH Corporation) are connected and used.
Column temperature: 40° C.
Sample Concentration: 0.1% by mass
Flow rate: 0.35 mL/min
Calibration curve: TSK standard polystyrene (manufactured by TOSOH Corporation), calibration curves of 6 samples with Mw of 706,000 to 1,013 (Mw/Mn=1.03 to 1.06) are used

### Solvent

From the viewpoint of workability and the like, the liquid crystal composition preferably contains a solvent.

Examples of the solvent include organic solvents such as ketones (such as acetone, 2-butanone, methyl ethyl ketone, methyl isobutyl ketone, cyclopentanetanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated hydrocarbons (such as dichloromethane, trichloromethane (chloroform), dichloroethane, dichlorobenzene, and chlorotoluene), esters (such as methyl acetate, ethyl acetate, ethyl propionate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water.

These solvents may be used alone or in combination of two or more kinds thereof.

Among these solvents, from the reason that the aligning properties of the optically anisotropic film to be formed are improved, an organic solvent is preferably used, and ketones and/or esters are more preferably used.

### Polymerization Initiator

The liquid crystal composition may contain a polymerization initiator. The polymerization initiator is not particularly limited, but a compound having photosensitivity, that is, a photopolymerization initiator is preferable.

As the photopolymerization initiator, various compounds can be used without any particular limitation. Examples of the photopolymerization initiator include an α-carbonyl compound, acyloin ether, an a-hydrocarbon-substituted aromatic acyloin compound, a polynuclear quinone compound, a combination of a triarylimidazole dimer and p-aminophenyl ketone, an acridine and phenazine compound, an oxadiazole compound, an o-acyloxime compound, and an acylphosphine oxide compound.

Commercially available products can also be used as such a photopolymerization initiator, and examples thereof include IRGACURE-184, IRGACURE-907, IRGACURE-369, IRGACURE-651, IRGACURE-819, IRGACURE-OXE-01, and IRGACURE-OXE-02, manufactured by BASF SE.

In a case where the liquid crystal composition contains a polymerization initiator, a content of the polymerization initiator is preferably 0.01% to 30% by mass and more preferably 0.1% to 15% by mass with respect to the total solid content (100% by mass) of the liquid crystal composition.

### Method for Producing Optically Anisotropic Film

Examples of a method for producing the optically anisotropic film according to the embodiment of the present invention include a method of using the above-described liquid crystal composition according to the present invention to obtain a desired alignment state, and then fixing the alignment state by polymerization.

Here, the alignment state is not particularly limited, and may be any of a horizontal alignment state, a vertical alignment state, a tilt alignment state, or a twisted alignment state.

In addition, polymerization conditions are not particularly limited, but ultraviolet rays are preferably used in the polymerization by light irradiation. An irradiation amount is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In order to promote the polymerization reaction, the treatment may be performed under heating conditions.

The optically anisotropic film can be formed on any support or alignment film in the optical film described later, or on a polarizer in the polarizing plate described later.

The optically anisotropic film according to the embodiment of the present invention is preferably a positive C-plate and a negative C-plate.

Here, the positive C-plate satisfies a relationship represented by the expression (C1) and the negative C-plate satisfies a relationship represented by the expression (C2). The positive C-plate has an Rth showing a negative value and the negative C-plate has an Rth showing a positive value.

$$nz > nx \approx ny \qquad Expression ( C1 )$$

$$nz < nx \approx ny \qquad Expression ( C2 )$$

The symbol “˜” encompasses not only a case where both sides are completely the same as each other but also a case where the both sides are substantially the same as each other. The expression “substantially the same” means that, for example, a case where (nx−ny)×d (in which d is a thickness of a film) is 0 to 10 nm and preferably 0 to 5 nm is also included in “nx ˜ny”.

### Optical Film

The optical film according to the embodiment of the present invention is an optical film having the optically anisotropic film according to the embodiment of the present invention.

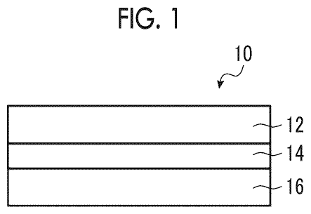

A structure of the optical film will be described with reference to FIG. 1. FIG. 1 is a schematic cross-sectional view showing an example of the optical film.

FIG. 1 is a schematic view, and the thicknesses relationship, the positional relationship, and the like of the respective layers are not necessarily consistent with actual ones; and a support and an alignment film shown in FIG. 1 are optional constitutional members.

An optical film 10 shown in FIG. 1 has a support 16, an alignment film 14, and an optically anisotropic film 12 according to the embodiment of the present invention in this order.

In addition, the optically anisotropic film 12 may be a laminate of two or more different optically anisotropic films. For example, in a case where the polarizing plate according to the embodiment of the present invention, which will described later, is used as a circularly polarizing plate or the optical film according to the embodiment of the present invention is used as an optical compensation film of an in-plane-switching (IPS) type or a fringe-field-switching (FFS) type liquid crystal display device, it is preferable that the optically anisotropic film is a laminate of a positive A-plate and a positive C-plate.

In addition, the optically anisotropic film may be peeled off from the support and used alone as the optical film.

Hereinafter, various members used for the optical film will be described in detail.

### Optically Anisotropic Film

The optically anisotropic film included in the optical film according to the embodiment of the present invention is the above-described optically anisotropic film according to the embodiment of the present invention.

In the optical film, a thickness of the above-described optically anisotropic film is not particularly limited, but is preferably 0.1 to 10 μm and more preferably 0.5 to 5 μm.

### Support

The optical film may have a support as a substrate for forming the optically anisotropic film as described above.

Such a support is preferably transparent. Specifically, a light transmittance thereof is preferably 80% or more.

Examples of such a support include a glass substrate and a polymer film. Examples of a material of the polymer film include cellulose-based polymers; acrylic polymers having an acrylic acid ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, an aspect in which a polarizer described later may also function as the support is also adopted.

A thickness of the above-described support is not particularly limited, but is preferably 5 to 100 μm, and more preferably 5 to 50 μm. The support is preferably peelable.

### Alignment Film

In the optical film, it is preferable that the optically anisotropic film is formed on a surface of the alignment film. In a case where the optical film has any of the above-described supports, the alignment film may be interposed between the support and the optically anisotropic film. In addition, an aspect in which the above-described support may also function as the alignment film is also adopted.

The alignment film may be any film as long as it has a function of aligning the polymerizable liquid crystal compound contained in the composition.

The alignment film generally contains a polymer as a main component. A polymer material for the alignment film is described in many documents, and many commercially available products can be used.

As the polymer material for the alignment film, a polyvinyl alcohol, a polyimide, or a derivative thereof is preferable, and a modified or unmodified polyvinyl alcohol is more preferable.

Since an object does not come into contact with a surface of the alignment film in the formation of the alignment film and the deterioration of a surface condition can be prevented, it is also preferable to use a photo-alignment film as the alignment film.

The photo-alignment film is not particularly limited; but an alignment film formed by a polymer material such as a polyamide compound and a polyimide compound described in paragraphs [0024] to [0043] of WO2005/096041A, a liquid crystal alignment film formed by a liquid crystal aligning agent having a cinnamoyl group described in JP2012-155308A, trade name LPP-JP265CP manufactured by Rolic Technologies Ltd., or the like can be used.

A thickness of the alignment film is not particularly limited, but from the viewpoint of forming an optically anisotropic film having a uniform film thickness by relaxing the surface roughness which can be present on the support, the thickness is preferably 0.01 to 10 μm, more preferably 0.01 to 1 μm, and still more preferably 0.01 to 0.5 μm.

### Polarizing Plate

The polarizing plate according to the embodiment of the present invention includes the above-described optically anisotropic film according to the embodiment of the present invention and a polarizer.

Here, the polarizer is not particularly limited as long as the polarizer is a member having a function of converting light into specific linearly polarized light, and a known absorptive type polarizer, reflective type polarizer, and coating type polarizer in the related art can be used.

An iodine-based polarizer, a dye-based polarizer using a dichroic dye, a polyene-based polarizer, or the like is used as the absorptive type polarizer. The iodine-based polarizer and the dye-based polarizer include a coating type polarizer and a stretching type polarizer, and any one of these polarizers can be applied. However, a polarizer which is produced by allowing polyvinyl alcohol to adsorb iodine or a dichroic dye and performing stretching is preferable.

Examples of the coating type polarizer include a polarizer containing a cured product of a liquid crystal compound and a dichroic coloring agent.

A polarizer in which thin films having different birefringence are laminated, a wire grid type polarizer, a polarizer in which a cholesteric liquid crystal having a selective reflection range and a ¼ wavelength plate are combined, or the like is used as the reflective type polarizer.

A thickness of the polarizer is not particularly limited, but is preferably 3 to 60 μm, more preferably 3 to 30 μm, and still more preferably 3 to 10 μm.

### Pressure Sensitive Adhesive Layer

The polarizing plate may include a pressure sensitive adhesive layer disposed between the optically anisotropic film in the optical film and the polarizer.

Examples of a material forming the pressure sensitive adhesive layer used for laminating the cured product and the polarizer include a member formed of a substance in which a ratio (tan δ=G″/G′) between a storage elastic modulus G′ and a loss elastic modulus G″, each measured with a dynamic viscoelasticity measurement device, is 0.001 to 1.5, in which a so-called pressure sensitive adhesive and a readily creepable substance are contained. Examples of the pressure sensitive adhesive include a polyvinyl alcohol-based pressure sensitive adhesive, but the pressure sensitive adhesive is not limited thereto.

### Adhesive Layer

The polarizing plate according to the embodiment of the present invention may include a pressure sensitive adhesive layer disposed between the optically anisotropic film in the optical film according to the embodiment of the present invention and the polarizer.

As the adhesive layer used for laminating the cured product and the polarizer, a curable adhesive composition which is cured by irradiation with active energy rays or heating is preferable.

Examples of the curable adhesive composition include a curable adhesive composition containing a cationically polymerizable compound and a curable adhesive composition containing a radically polymerizable compound.

A thickness of the adhesive layer is preferably 0.01 to 20 μm, more preferably 0.01 to 10 μm, and still more preferably 0.05 to 5 μm. In a case where the thickness of the adhesive layer is within the range, floating or peeling does not occur between the protective layer or optically anisotropic film and the polarizer, which are laminated, and an adhesive force having no problem in practical use can be obtained. In addition, the thickness of the adhesive layer is preferably 0.4 μm or more from the viewpoint that generation of air bubbles can be suppressed.

With regard to the adhesive layer, reference can be made to, for example, the description in paragraphs to of JP2016-35579A, the contents of which are incorporated herein by reference.

### Easy Adhesion Layer

The polarizing plate according to the embodiment of the present invention may include an easy adhesion layer disposed between the optically anisotropic film in the optical film according to the embodiment of the present invention and the polarizer. From the viewpoint of excellent adhesiveness between the optically anisotropic film and the polarizer and further suppressing the occurrence of cracks in the polarizer, a storage elastic modulus of the easy adhesion layer at 85° C. is preferably 1.0×10⁶ Pa to 1.0×10⁷ Pa. Examples of a constituent material of the easy adhesion layer include a polyolefin-based component and a polyvinyl alcohol-based component. A thickness of the easy adhesion layer is preferably 500 nm to 1 μm.

With regard to the easy adhesion layer, reference can be made to, for example, the description in paragraphs to of [0048] to [0053] JP2018-36345A, the contents of which are incorporated herein by reference.

### Image Display Apparatus

The image display apparatus according to the embodiment of the present invention is an image display apparatus including the optically anisotropic film according to the embodiment of the present invention.

A display element used in the image display apparatus is not particularly limited, and examples thereof include a liquid crystal cell, an organic electroluminescent (hereinafter, simply referred to as “EL”) display panel, and a plasma display panel. Among these, a liquid crystal cell or an organic EL display panel is preferable.

### Liquid Crystal Display Device

A liquid crystal display device as an example of the image display apparatus is a liquid crystal display device including the above-described polarizing plate and a liquid crystal cell.

Among polarizing plates provided on both sides of the liquid crystal cell, it is preferable that the above-described polarizing plate is used as a polarizing plate on the front side, and it is more preferable that the above-described polarizing plate is used as polarizing plates on the front and rear sides.

### Liquid Crystal Cell

It is preferable that the liquid crystal cell used in the liquid crystal display device is in a vertical alignment (VA) mode, an optically compensated bend (OCB) mode, an in-plane-switching (IPS) mode, a fringe-field-switching (FFS) mode, or a twisted nematic (TN) mode, but is not limited thereto.

### Organic EL Display Device

Examples of the organic EL display device which is an example of the image display apparatus include an aspect which includes, from a viewing side, a polarizer, a λ/4 plate including the above-described optically anisotropic film, and an organic EL display panel in this order.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinbelow, the present invention will be described in more detail with reference to Examples. The materials, amounts used, proportions, treatment contents, treatment procedures, and the like shown in the following examples can be modified as appropriate in the range of not departing from the spirit of the present invention. Therefore, the scope of the present invention should not be construed as being limited to Examples.

### Example 1

### Production of Optically Anisotropic Film A

A liquid crystal composition A having the following formulation was applied onto TAC1 (cellulose-based polymer film ZRD40, manufactured by FUJIFILM Corporation) as a temporary support with a die coater.

Next, the coating film was heated with hot air at 60° C. for 60 seconds in order to dry the solvent of the liquid crystal composition A and to align and age the liquid crystal compound.

Next, the coating film was irradiated with ultraviolet rays (120 mJ/cm²) at 60° C. and an oxygen concentration of 100 ppm under nitrogen purge to fix the alignment of the liquid crystal compound, thereby producing a film A having an optically anisotropic film A on the temporary support. The optically anisotropic film A had a thickness of 0.7 μm, Re(550) of 0 nm, and Rth(550) of −80 nm.

Liquid crystal composition A

| | | |
|---|---|---|
| Rod-like liquid crystal compound (LC-1) shown | 83 | parts by mass |
| below | | |
| Rod-like liquid crystal compound (LC-2) shown | 15 | parts by mass |
| below | | |
| Rod-like liquid crystal compound (LC-3) shown | 2 | parts by mass |
| below | | |
| Polymerizable monomer (UA-601I, manufactured | 5.0 | parts by mass |
| by KYOEISHA CHEMICAL Co., LTD.) | | |
| Polymerization initiator (Irgacure OXE01, | 4.0 | parts by mass |
| manufactured by BASF SE) | | |
| Fluorine-containing polymer (FA-1) shown below | 1.5 | parts by mass |
| Fluorine-containing polymer (FB-1) shown below | 0.3 | parts by mass |
| Onium salt compound (S01) shown below | 1.25 | parts by mass |
| Toluene | 508 | parts by mass |
| Methyl ethyl ketone (MEK) | 127 | parts by mass |

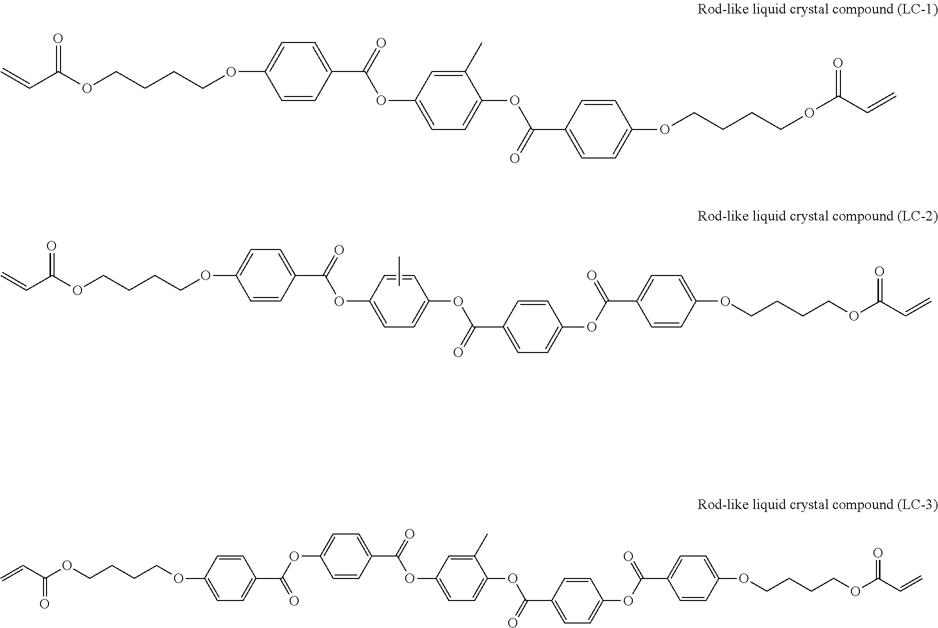

Fluorine-containing polymer (FA-1) [in the following formula, a numerical value described in each repeating unit indicates a content (% by mass) of each repeating unit with respect to all repeating units; weight-average molecular weight: 23,500]

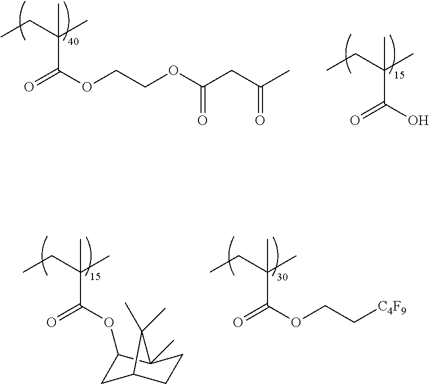

Fluorine-containing polymer (FB-1) [in the following formula, a numerical value described in each repeating unit indicates a content (% by mass) of each repeating unit with respect to all repeating units; weight-average molecular weight: 13,000]

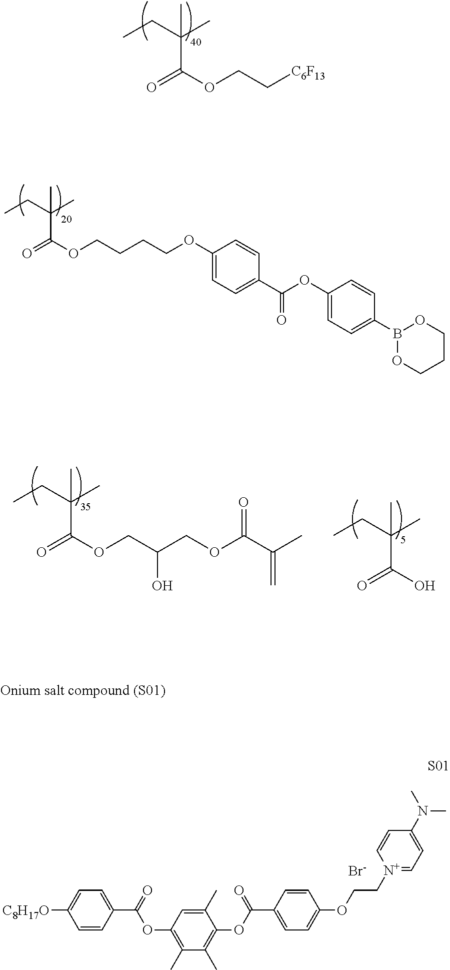

### Evaluation

The produced optically anisotropic film A was evaluated by the following method. The results are shown in Table 1 below.

### Evaluation of Surface Energy of Single Film of Fluorine-Containing Polymer

The above-described fluorine-containing polymer (FA-1) was diluted to be 0.4% using MEK to prepare a diluted liquid.

Next, the above-described diluted liquid was applied onto TAC1 (cellulose-based polymer film ZRD40, manufactured by FUJIFILM Corporation) with a spin coater (3,000 rpm), and dried on a hot plate at 70° C. for 1 minute to form a single film of the fluorine-containing polymer (FA-1) on the film.

Next, contact angles of a surface of the single film with respect to pure water and diiodomethane were measured, and the surface energy was calculated by substituting the measured values into the equation of the surface energy of Owens.

A single film of the fluorine-containing polymer (FB-1) was produced by the same method, and the surface energy thereof was calculated.

### Evaluation of Distribution of Fluorine-Containing Polymer

A range of 900 μm² of the produced optically anisotropic film A was analyzed by TOF-SIMS (TOF-SIMS5, manufactured by IONTOF GmbH) while etching using Ar-GCIB.

The secondary ion intensity of a fragment corresponding to C₅F₇⁻ at the outermost surface (without etching) and at a depth of 5 nm was measured, and an abundance ratio R(A) of the fluorine-containing polymer (FA-1) at a depth of 5 nm with respect to the outermost surface was determined.

$$RA = ( Secondary ion intensity at 5 nm etching ) / ( Secondary ion intensity at outermost surface )$$

Similarly, an abundance ratio R(B) of the fluorine-containing polymer (FB-1) was determined from the secondary ion intensity ratio of a fragment of C₇F₁₁⁻.

### Evaluation of Liquid Crystal Alignment Properties

The film A produced as described above was observed with a polarization microscope under a crossed nicols condition using an objective lens at 10 times, and the number of alignment defects in a range of 2 mm² in a size of 1 μm or more and 10 μm or less was counted. The film A was observed in a total of 10 visual fields and evaluated according to the following standard.
A: number of alignment defects was less than 5 in all of the 10 visual fields.
B: there was a region where the number of alignment defects was 5 or more and less than 50 in the 10 visual fields.
C: there was a region where the number of alignment defects was 50 or more in the 10 visual fields, which is unacceptable.
D: entire surface was not aligned.

### Evaluation of Adhesiveness

Production of Liquid Crystal Film for Adhesion Test

A photo-alignment film P-1 was produced by the method shown in Example 1 of WO2019/159960A.

Next, a liquid crystal composition T for test, having the following formulation, was applied onto the photo-alignment film P-1, heated to 130° C. with hot air, cooled to 50° C., irradiated with ultraviolet rays at an irradiation amount of 100 mJ/cm² at a wavelength of 365 nm using a high-pressure mercury lamp in a nitrogen atmosphere, heated to 120° C., and irradiated with ultraviolet rays at an irradiation amount of 150 mJ/cm² to be immobilized, thereby producing a film (T1) in which a liquid crystal film for an adhesion test, having a thickness of 3.0 μm, was provided on the photo-alignment film P-1.

Liquid crystal composition T for test

| | | |
|---|---|---|
| Rod-like liquid crystal compound (LC-1) | 6.6 | parts by mass |
| shown above | | |
| Rod-like liquid crystal compound (LC-2) | 1.2 | parts by mass |
| shown above | | |
| Rod-like liquid crystal compound (LC-3) | 0.2 | parts by mass |
| shown above | | |
| Rod-like liquid crystal compound (LC-4) | 45 | parts by mass |
| shown below | | |
| Rod-like liquid crystal compound (LC-5) | 22 | parts by mass |
| shown below | | |
| Rod-like liquid crystal compound (LC-6) | 20 | parts by mass |
| shown below | | |
| Rod-like liquid crystal compound (LC-7) | 5 | parts by mass |
| shown below | | |
| Polymerization initiator PI-1 shown below | 0.5 | parts by mass |
| Leveling agent P1 shown below | 0.1 | parts by mass |
| Methyl ethyl ketone | 54 | parts by mass |
| Cyclopentanone | 181 | parts by mass |

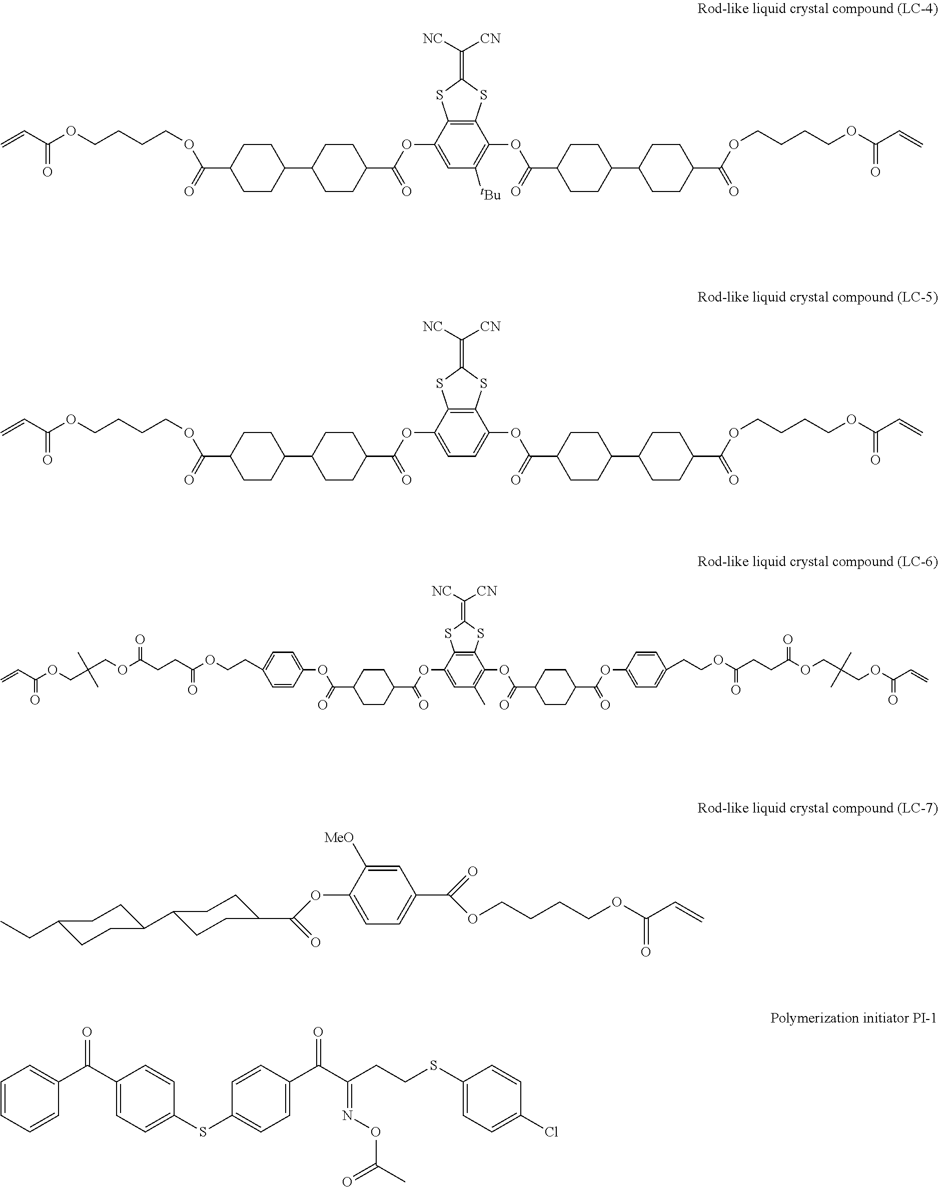

Leveling agent P1 [the numerical value in the following formula indicates the content (% by mass) of each repeating unit with respect to all repeating units in the leveling agent P1; weight-average molecular weight: 17,000]

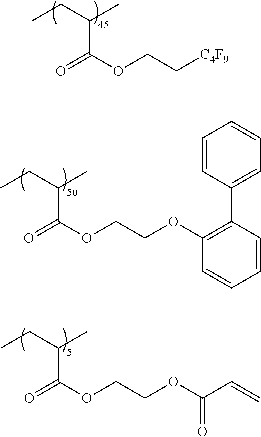

### Production of Polarizing Plate

After performing a corona treatment (32 W·min/m²) on the surface of the optically anisotropic film A of the above-described film A, the following active energy ray-curable adhesive composition was applied as an UV-curable adhesive to form an adhesive coated film (T2).

Next, a corona treatment (63 W·min/m²) was performed on the coated surface (liquid crystal film side) of the above-described film (T1), and the corona-treated surface was bonded to the adhesive surface of the above-described adhesive coated film (T2).

Thereafter, one surface of the film (T1) was irradiated with ultraviolet rays at 150 mJ/cm² from the optically anisotropic film A side, and then dried with hot air at 100° C. for 1 minute to form an adhesive layer. Thereafter, the support of the film (T1) was peeled off together with the photo-alignment film to produce a laminated film (T3).

Active energy ray-curable adhesive composition

| | | |
|---|---|---|
| CELLOXIDE 2021P (manufactured by Daicel | 40.2 | parts by mass |
| Corporation) | | |
| 2-Ethylhexyl glycidyl ether | 5.74 | parts by mass |
| RIKARESIN DME-100 (manufactured by | 11.47 | parts by mass |
| New Japan Chemical Co., Ltd.) | | |
| CPI-100 (manufactured by San-Apro Ltd.) | 2.57 | parts by mass |

### Production of Evaluation Sample

A polarizing plate in which a polarizer was exposed on one side was obtained by a method described in paragraph [0162] of JP2019-159960A. The liquid crystal film side of the above-described laminated film (T3) was bonded to the exposed polarizer through a pressure sensitive adhesive (SK2057, manufactured by Soken Chemical & Engineering Co., Ltd.), and then the temporary support of the film A was peeled off to produce an evaluation sample in which the optically anisotropic film A was exposed.

### Evaluation of Adhesiveness With Adhesive Layer

The surface of the optically anisotropic film A in the evaluation sample was cut vertically and horizontally at intervals of 1 mm to form 100 squares.

Next, a pressure sensitive adhesive tape (manufactured by Nitto Denko Corporation, NO. 31B75 HI) was bonded over the cuts, and the tape was peeled off every 20 minutes in a sufficiently closely attached state three times. Thereafter, the number of squares from which the optically anisotropic film A was peeled off was counted.
A: number of squares from which the film was peeled off was 5 or less.
B: number of squares from which the film was peeled off was 6 or more and 20 or less.
C: number of squares from which the film was peeled off was 21 or more and 50 or less.
D: number of squares from which the film was peeled off was 51 or more.

### Example 2

An optically anisotropic film B was produced and evaluated in the same manner as in Example 1, except that the above-described fluorine-containing polymer (FA-1) blended in the liquid crystal composition A was changed to the following fluorine-containing polymer (FA-2).

Fluorine-containing polymer (FA-2) [in the following formula, a numerical value described in each repeating unit indicates a content (% by mass) of each repeating unit with respect to all repeating units; weight-average molecular weight: 22,000]

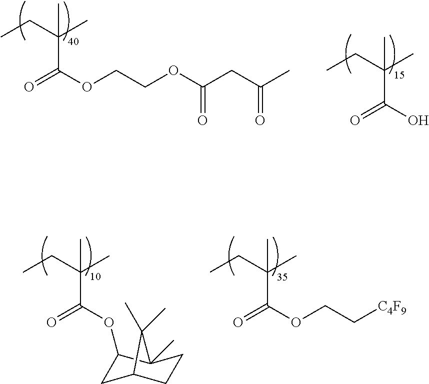

### Example 3

An optically anisotropic film C was produced and evaluated in the same manner as in Example 1, except that the blending amount of the above-described fluorine-containing polymer (FA-1) blended in the liquid crystal composition A was changed to 1.8 parts by mass and the blending amount of the above-described onium salt compound (S01) was changed to 1.5 parts by mass.

### Comparative Example 1

An optically anisotropic film D was produced and evaluated in the same manner as in Example 1, except that the blending amount of the above-described fluorine-containing polymer (FA-1) blended in the liquid crystal composition A was changed to 3.0 parts by mass and the blending amount of the above-described onium salt compound (S01) was changed to 2.5 parts by mass.

### Comparative Example 2

An optically anisotropic film E was produced and evaluated in the same manner as in Example 1, except that the blending amount of the above-described fluorine-containing polymer (FA-1) blended in the liquid crystal composition A was changed to 1.0 part by mass and the blending amount of the above-described onium salt compound (S01) was changed to 0.83 parts by mass.

### Example 4

An optically anisotropic film F was produced and evaluated in the same manner as in Example 1, except that the blending amount of the above-described fluorine-containing polymer (FA-1) blended in the liquid crystal composition A was changed to 1.0 part by mass, the blending amount of the above-described onium salt compound (S01) was changed to 0.83 part by mass, the blending amount of methyl ethyl ketone was changed to 191 parts by mass, and the blending amount of toluene was changed to 444 parts by mass.

TABLE 1

| | | Fluorine-containing polymer (A) | | | Fluorine-containing polymer (B) | |
|---|---|---|---|---|---|---|
| | | | Surface | Content of | | Surface |
| | Optically | | energy of | repeating | | energy of |
| | anisotropic | | single film | unit F | | single film |
| | film | Type | (mN/m) | (% by mass) | Type | (mN/m) |
| Example 1 | A | FA-1 | 25.0 | 30 | FB-1 | 14.3 |
| Example 2 | B | FA-2 | 24.1 | 35 | FB-1 | 14.3 |
| Example 3 | C | FA-1 | 25.0 | 30 | FB-1 | 14.3 |
| Comparative Example 1 | D | FA-1 | 25.0 | 30 | FB-1 | 14.3 |
| Comparative Example 2 | E | FA-1 | 25.0 | 30 | FB-1 | 14.3 |
| Example 4 | F | FA-1 | 25.0 | 30 | FB-1 | 14.3 |

| | | | | | | Evaluation | | |
|---|---|---|---|---|---|---|---|---|
| | | | | | | | Liquid | |
| | | | | | | | crystal | Adhesiveness |
| | Part by mass in composition | | | | | R(A)/ | alignment | with adjacent |
| | FA-1 | FA-2 | S01 | MEK | Toluene | R(B) | properties | layer |
| Example 1 | 1.5 | — | 1.25 | 127 | 508 | 19 | B | A |
| Example 2 | — | 1.5 | 1.25 | 127 | 508 | 14 | A | A |
| Example 3 | 1.8 | — | 1.5 | 127 | 508 | 30 | A | B |
| Comparative Example 1 | 3.0 | — | 2.5 | 127 | 508 | 60 | A | D |
| Comparative Example 2 | 1.0 | — | 0.83 | 127 | 508 | 1 | C | A |
| Example 4 | 1.0 | — | 0.83 | 191 | 444 | 11 | B | A |

From the results shown in Table 1, it was found that, in a case where the value of “R(A)/R(B)” was large, the adhesiveness with the adjacent layer was deteriorated (Comparative Example 1).

In addition, it was found that, in a case where the value of “R(A)/R(B)” was small, the liquid crystal alignment properties were deteriorated (Comparative Example 2).

On the other hand, it was found that, in a case where the value of “R(A)/R(B)” was 5 to 50, the liquid crystal alignment properties were excellent and the adhesiveness with the adjacent layer was also excellent (Examples 1 to 4).

In addition, from Examples 1 to 4, it was found that “R(A)/R(B)” could be adjusted by the kind of the fluorine-containing polymer, the content of the additive, the solvent formulation, and the like. It is presumed that the change in “R(A)/R(B)” depending on the solvent formulation is due to a difference in drying rate.

### Comparative Example 3

An optically anisotropic film G was produced and evaluated in the same manner as in Example 1, except that the above-described fluorine-containing polymer (FB-1) blended in the liquid crystal composition A was changed to the following fluorine-containing polymer (FB-2).

Fluorine-containing polymer (FB-2) [in the following formula, a numerical value described in each repeating unit indicates a content (% by mass) of each repeating unit with respect to all repeating units: weight-average molecular weight: 13,0001]

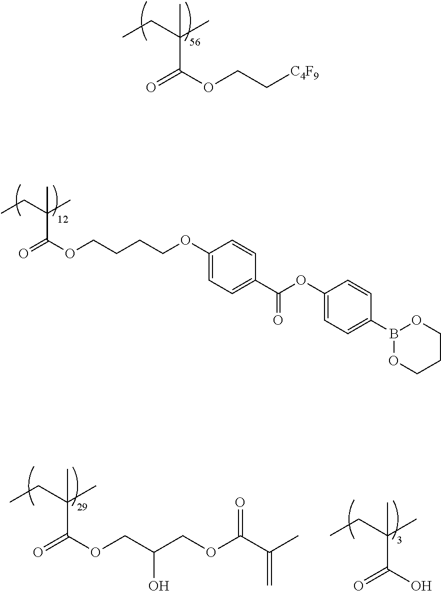

### Comparative Example 4

An optically anisotropic film H was produced and evaluated in the same manner as in Comparative Example 3, except that the blending amount of the above-described fluorine-containing polymer (FB-2) was changed to 3.0 parts by mass and the blending amount of the above-described onium salt compound (S01) was changed to 2.5 parts by mass.

### Comparative Example 5

An optically anisotropic film I was produced and evaluated in the same manner as in Comparative Example 3, except that the blending amount of the above-described fluorine-containing polymer (FB-2) was changed to 1.0 part by mass and the blending amount of the above-described onium salt compound (S01) was changed to 0.83 parts by mass.

TABLE 2

| | | Fluorine-containing polymer (A) | | | Fluorine-containing polymer (B) | | |
|---|---|---|---|---|---|---|---|
| | | | Surface | Content of | | Surface | Number of |
| | Optically | | energy of | repeating | | energy of | carbon atoms |
| | anisotropic | | single film | unit F | | single film | in fluoroalkyl |
| | film | Type | (mN/m) | (% by mass) | Type | (mN/m) | group |
| Example 1 | A | FA-1 | 25.0 | 4 | FB-1 | 14.3 | 6 |
| Comparative Example 3 | G | FA-1 | 25.0 | 4 | FB-2 | 19.9 | 4 |
| Comparative Example 4 | H | FA-1 | 25.0 | 4 | FB-2 | 19.9 | 4 |
| Comparative Example 5 | T | FA-1 | 25.0 | 4 | FB-2 | 19.9 | 4 |

| | | | | | Evaluation | | |
|---|---|---|---|---|---|---|---|
| | | | | | | Liquid | |
| | | | | | | crystal | Adhesiveness |
| | Part by mass in composition | | | | R(A)/ | alignment | with adjacent |
| | FA-1 | FB-1 | FB-2 | S01 | R(B) | properties | layer |
| Example 1 | 1.5 | 0.3 | — | 1.25 | 19 | B | A |
| Comparative Example 3 | 1.5 | — | 0.3 | 1.25 | 1 | C | A |
| Comparative Example 4 | 1.5 | — | 3.0 | 2.5 | 2 | C | A |
| Comparative Example 5 | 1.5 | — | 1.0 | 0.83 | 1 | C | A |

From the results shown in Table 2, it was found that, in a case where there was no difference in the number of carbon atoms in the fluoroalkyl groups of the fluorine-containing polymers A and B, the value of “R(A)/R(B)” was small, and thus the liquid crystal alignment properties were deteriorated (Comparative Examples 3 to 5).

### Comparative Example 6

An optically anisotropic film J was produced in the same manner as a transfer film described in paragraphs [0071] to [0080] of WO2020/067291A, and evaluated in the same manner as in Example 1. In a case where a fluorine-containing polymer (M-6) (surface energy of the single film: 31.5 mN/m) contained in the above-described liquid crystal layer-forming composition 1 was regarded as the fluorine-containing polymer A, and a fluorine-containing polymer (M-5) (same formulation as that of the above-described fluorine-containing polymer (FA-1)) was regarded as the fluorine-containing polymer B, R(A)/R(B) was 0.02. The liquid crystal alignment properties of the optically anisotropic film J were evaluated as A, and the adhesiveness with the adjacent layer was evaluated as D.

### Comparative Example 7

Based on a method for producing an optical film described in paragraphs [0143] to [0153] of WO2020/067291A, a cycloolefin polymer film of the substrate was changed to a polyethylene terephthalate film to produce an optically anisotropic film L, and the optically anisotropic film L was evaluated in the same manner as in Example 1. In a case where a surfactant (S1) (surface energy of the single film: 20.9 mN/m) contained in the above-described liquid crystal layer-forming composition 1 was regarded as the fluorine-containing polymer A, and a surfactant (S2) (same formulation as that of the above-described fluorine-containing polymer (FB-1)) was regarded as the fluorine-containing polymer B, R(A)/R(B) was 1. In addition, the liquid crystal alignment properties of the optically anisotropic film L were evaluated as C, and the adhesiveness with the adjacent layer was evaluated as A.

### Comparative Example 8

An optically anisotropic film M was produced using a liquid crystal composition A of Example 1 by a method described in paragraphs [0066] to [0079] of WO2019/022156A, and evaluated. In a case where a fluorine-containing compound (F-3) (surface energy of the single film: 20.9 mN/m) or a fluorine-containing compound (F-1) (surface energy of the single film: 31.5 mN/m) contained in the above-described coating liquid A for the optically anisotropic layer was regarded as the fluorine-containing polymer A, and a fluorine-containing compound (F-2) (surface energy of the single film: 17.1 mN/m) was regarded as the fluorine-containing polymer B, both of R(A)/R(B)=1. In addition, the liquid crystal alignment properties of the optically anisotropic film M were evaluated as C, and the adhesiveness with the adjacent layer was evaluated as D.

### Reference Example 1

An optically anisotropic film N was produced and evaluated in the same manner as in Example 1, except that the fluorine-containing polymers (FA-1) and (FB-1) were not blended in the liquid crystal composition A.

### Reference Example 2

An optically anisotropic film O was produced and evaluated in the same manner as in Example 1, except that the fluorine-containing polymer (FB-1) was not blended in the liquid crystal composition A.

TABLE 3

| | | Fluorine-containing | | Fluorine-containing | | | | | | | |
|---|---|---|---|---|---|---|---|---|---|---|---|
| | | polymer (A) | | polymer (B) | | | | | Evaluation | | |
| | | | Surface | | Surface | | | | | Liquid | Adhesiveness |
| | Optically | | energy of | | energy of | | Equivalent in | | | crystal | with |
| | anisotropic | | single film | | single film | Reactive | composition | | R(A)/ | alignment | adjacent |
| | film | Type | (mN/m) | Type | (mN/m) | group | FA-1 | FB-1 | R(B) | properties | layer |
| Example 1 | A | FA-1 | 25.0 | FB-1 | 14.3 | Acrylate/ | 1.5 | 0.3 | 19 | A | A |
| | | | | | | boronic acid | | | | | |
| Reference | N | — | — | — | — | — | — | — | — | D | A |
| Example 1 | | | | | | | | | | | |
| Reference | O | — | — | — | — | — | 1.5 | — | — | A | D |
| Example 2 | | | | | | | | | | | |

As shown in Table 3, from the comparison between Reference Example 1 and Reference Example 2, it was found that, in a case where the fluorine-containing polymer (FA-1) was added, the liquid crystal alignment properties were improved, but the adhesiveness was deteriorated.

In addition, from the comparison between Example 1 and Reference Example 2, it was found that the fluorine-containing polymer (FB-1) improved the adhesiveness with the adjacent layer.

### Example 5

An optically anisotropic film P was produced and evaluated in the same manner as in Example 1, except that the liquid crystal composition A was changed to the following liquid crystal composition P.

Liquid crystal composition P

| | | |
|---|---|---|
| Rod-like liquid crystal compound (LC-1) | 83 | parts by mass |
| shown above | | |
| Rod-like liquid crystal compound (LC-2) | 15 | parts by mass |
| shown above | | |
| Rod-like liquid crystal compound (LC-3) | 2 | parts by mass |
| shown above | | |
| Polymerizable monomer (UA-601I, manufactured | 5.0 | parts by mass |
| by KYOEISHA CHEMICAL Co., LTD.) | | |
| Polymerization initiator (Irgacure OXE01, | 4.0 | parts by mass |
| manufactured by BASF SE) | | |
| Silicon-containing polymer (SiC-1) shown below | 1.5 | parts by mass |
| Silicon-containing polymer (SiD-1) shown below | 0.3 | parts by mass |
| Onium salt compound (S01) shown above | 1.25 | parts by mass |
| Toluene | 508 | parts by mass |
| Methyl ethyl ketone (MEK) | 127 | parts by mass |

Silicon-containing polymer (SiC-1) [in the following formula, a numerical value described in each repeating unit indicates a content (% by mass) of each repeating unit with respect to all repeating units; weight-average molecular weight: 15,000]

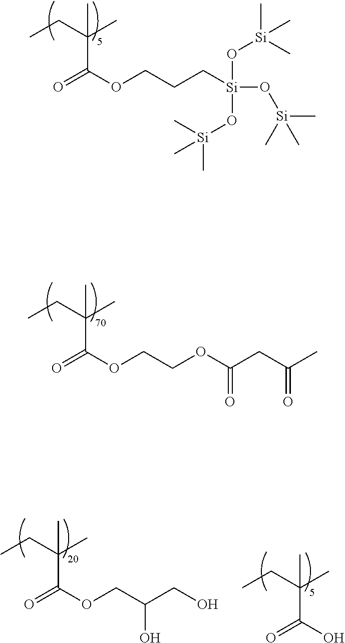

Silicon-containing polymer (SiD-1) [in the following formula, a numerical value described in each repeating unit indicates a content (% by mass) of each repeating unit with respect to all repeating units; weight-average molecular weight: 12,000]

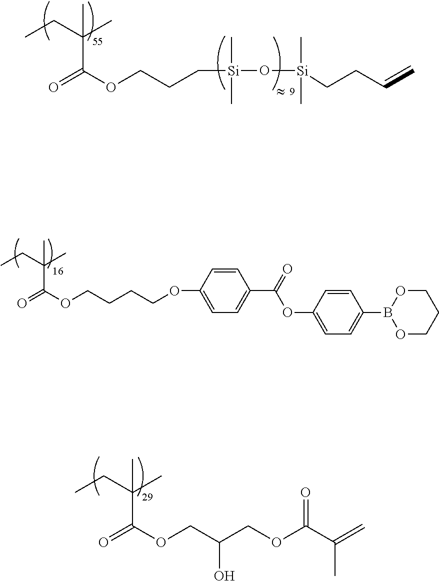

### Comparative Example 9

An optically anisotropic film Q was produced and evaluated in the same manner as in Example 5, except that the silicon-containing polymer SiD-1 was changed to the following silicon-containing polymer SiD-2.

Silicon-containing polymer (SiD-2) [in the following formula, a numerical value described in each repeating unit indicates a content (% by mass) of each repeating unit with respect to all repeating units; weight-average molecular weight: 12,500]

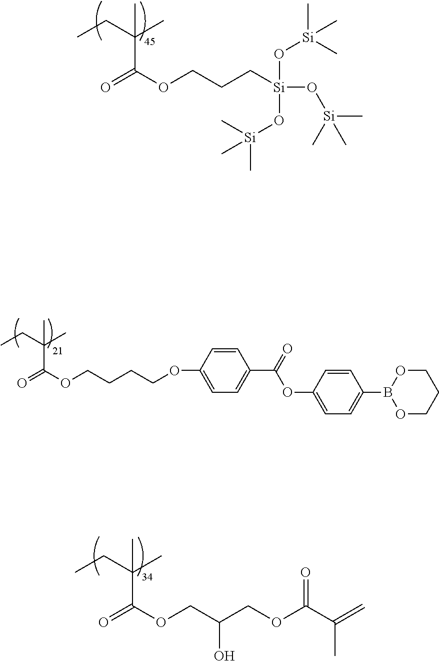

### Comparative Example 10

An optically anisotropic film R was produced and evaluated in the same manner as in Example 5, except that the silicon-containing polymer SiD-1 was changed to the following silicon-containing polymer SiD-3.

Silicon-containing polymer (SiD-3) [in the following formula, a numerical value described in each repeating unit indicates a content (% by mass) of each repeating unit with respect to all repeating units; weight-average molecular weight: 13,000]

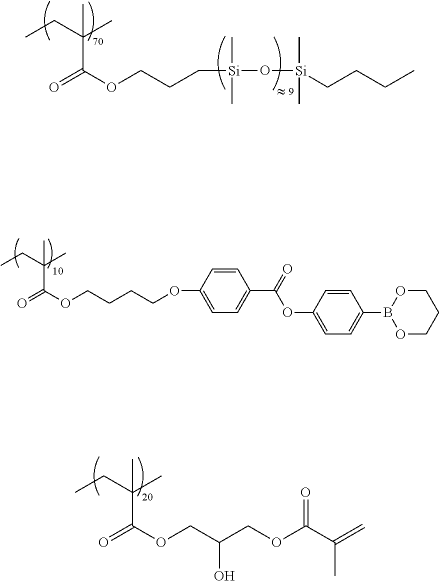

TABLE 4

| | | Fluorine-containing | | Fluorine-containing | | | | | | | | | |
|---|---|---|---|---|---|---|---|---|---|---|---|---|---|
| | | polymer (C) | | polymer (D) | | | | | | | Evaluation | | |
| | | | Surface | | Surface | | | | | | | Liquid | |
| | Optically | | energy of | | energy of | | Equivalent in | | | | | crystal | Adhesiveness |
| | anisotropic | | single film | | single film | Reactive | composition | | | | R(C)/ | alignment | with adjacent |
| | film | Type | (mN/m) | Type | (mN/m) | group | SiC-1 | SiD-1 | SiD-2 | SiD-3 | R(D) | properties | layer |
| Example 5 | P | SiC-1 | 28.0 | SiD-1 | 22.5 | Acrylate/ | 0.8 | 0.5 | | | 8 | A | B |
| | | | | | | boronic acid | | | | | | | |
| Comparative | Q | SiC-1 | 28.0 | SiD-2 | 24.8 | Acrylate/ | 0.8 | | 0.5 | | 2 | C | B |
| Example 9 | | | | | | boronic acid | | | | | | | |
| Comparative | R | SiC-1 | 28.0 | SiD-3 | 21.2 | Acrylate/ | 0.8 | | | 0.5 | 55 | A | D |
| Example 10 | | | | | | boronic acid | | | | | | | |

From the results shown in Table 4, it was found that, in a case where the value of “R(C)/R(D)” was large, the adhesiveness with the adjacent layer was deteriorated (Comparative Example 10).

In addition, it was found that, in a case where the value of “R(C)/R(D)” was small, the liquid crystal alignment properties were deteriorated (Comparative Example 9).

On the other hand, it was found that, in a case where the value of “R(C)/ (D)” was 5 to 50, the liquid crystal alignment properties were excellent and the adhesiveness with the adjacent layer was also excellent (Example 5).

The evaluation of the surface energy of the single film of the silicon-containing polymer and the evaluation of the distribution of the silicon-containing polymer were carried out under the same conditions as the evaluations for the fluorine-containing polymer.

### EXPLANATION OF REFERENCES

10: optical film
12: optically anisotropic film
14: alignment film
16: support

What is claimed is:

1. An optically anisotropic film obtained by fixing an alignment state of a liquid crystal composition,
wherein the liquid crystal composition contains a liquid crystal compound, a fluorine-containing polymer A, and a fluorine-containing polymer B, or contains a liquid crystal compound, a silicon-containing polymer C, and a silicon-containing polymer D,
a surface energy of a single film of the fluorine-containing polymer A is higher than a surface energy of a single film of the fluorine-containing polymer B, or a surface energy of a single film of the silicon-containing polymer C is higher than a surface energy of a single film of the silicon-containing polymer D, and
an abundance ratio R(A) represented by the following expression (1) and an abundance ratio R(B) represented by the following expression (2) satisfy a relationship represented by the following expression (3), or an abundance ratio R(C) represented by the following expression (4) and an abundance ratio R(D) represented by the following expression (5) satisfy a relationship represented by the following expression (6),
$$R ( A ) = MA ( 5 ) / MA ( 0 ) , \qquad ( 1 )$$
$$R ( B ) = MB ( 5 ) / MB ( 0 ) , \qquad ( 2 )$$
$$50 \geq R ( A ) / R ( B ) \geq 5 , \qquad ( 3 )$$
$$R ( C ) = MC ( 5 ) / MC ( 0 ) , \qquad ( 4 )$$
$$R ( D ) = MD ( 5 ) / MD ( 0 ) , \qquad ( 5 )$$
$$50 \geq R ( C ) / R ( D ) \geq 5 , \qquad ( 6 )$$
in the expression (1), MA(5) represents an amount of the fluorine-containing polymer A present at a position of 5 nm away from one surface X of the optically anisotropic film in a thickness direction, MA(0) represents an amount of the fluorine-containing polymer A present at the surface X, and MA(0) represents a value larger than MA(5),
in the expression (2), MB(5) represents an amount of the fluorine-containing polymer B present at a position of 5 nm away from the surface X in the thickness direction, MB(0) represents an amount of the fluorine-containing polymer B present at the surface X, and MB(0) represents a value larger than MB(5),
in the expression (4), MC(5) represents an amount of the silicon-containing polymer C present at a position of 5 nm away from the surface X in the thickness direction, MC(0) represents an amount of the silicon-containing polymer C present at the surface X, and MC(0) represents a value larger than MC(5),
in the expression (5), MD(5) represents an amount of the silicon-containing polymer D present at a position of 5 nm away from the surface X in the thickness direction, MD(0) represents an amount of the silicon-containing polymer D present at the surface X, and MD(0) represents a value larger than MD(5).

2. The optically anisotropic film according to claim 1,
wherein the liquid crystal composition contains a liquid crystal compound, a fluorine-containing polymer A, and a fluorine-containing polymer B,
a surface energy of a single film of the fluorine-containing polymer A is higher than a surface energy of a single film of the fluorine-containing polymer B, and
an abundance ratio R(A) represented by the following expression (1) and an abundance ratio R(B) represented by the following expression (2) satisfy a relationship represented by the following expression (3),
$$R ( A ) = MA ( 5 ) / MA ( 0 ) , \qquad ( 1 )$$
$$R ( B ) = MB ( 5 ) / MB ( 0 ) , \qquad ( 2 )$$
$$50 \geq R ( A ) / R ( B ) \geq 5 , \qquad ( 3 )$$
in the expression (1), MA(5) represents an amount of the fluorine-containing polymer A present at a position of 5 nm away from one surface X of the optically anisotropic film in a thickness direction, MA(0) represents an amount of the fluorine-containing polymer A present at the surface X, and MA(0) represents a value larger than MA(5),
in the expression (2), MB(5) represents an amount of the fluorine-containing polymer B present at a position of 5 nm away from the surface X in the thickness direction, MB(0) represents an amount of the fluorine-containing polymer B present at the surface X, and MB(0) represents a value larger than MB(5).

3. The optically anisotropic film according to claim 2,
wherein the fluorine-containing polymer B has a repeating unit including, in a side chain, at least one reactive group selected from the group consisting of an acryloyl group, a methacryloyl group, an epoxy group, and a boronic acid group.

4. The optically anisotropic film according to claim 2,
wherein the fluorine-containing polymer A has a repeating unit including, in a side chain, at least one polar group selected from the group consisting of a hydroxyl group and a carboxylic acid group.

5. The optically anisotropic film according to claim 2,
wherein the optically anisotropic film is a positive C-plate or a negative C-plate.

6. The optically anisotropic film according to claim 2,
wherein both the fluorine-containing polymer A and the fluorine-containing polymer B have a repeating unit, in a side chain, an alkyl group having 1 to 20 carbon atoms in which at least one hydrogen atom is replaced with a fluorine atom, and
a number of carbon atoms in the alkyl group of the fluorine-containing polymer A is smaller than a number of carbon atoms in the alkyl group of the fluorine-containing polymer B.

7. The optically anisotropic film according to claim 6,
wherein the number of carbon atoms in the alkyl group of the fluorine-containing polymer A is 4 or less.

8. The optically anisotropic film according to claim 2,
wherein a content of the fluorine-containing polymer A is higher than a content of the fluorine-containing polymer B.

9. An optical film comprising:
the optically anisotropic film according to claim 2.

10. A polarizing plate comprising:
the optically anisotropic film according to claim 2; and
a polarizer.

11. An image display apparatus comprising:
the optically anisotropic film according to claim 2.

12. The optically anisotropic film according to claim 1,
wherein the liquid crystal composition contains a liquid crystal compound, a silicon-containing polymer C, and a silicon-containing polymer D,
a surface energy of a single film of the silicon-containing polymer C is higher than a surface energy of a single film of the silicon-containing polymer D, and
an abundance ratio R(C) represented by the following expression (4) and an abundance ratio R(D) represented by the following expression (5) satisfy a relationship represented by the following expression (6),
$$R ( C ) = MC ( 5 ) / MC ( 0 ) , \qquad ( 4 )$$
$$R ( D ) = MD ( 5 ) / MD ( 0 ) , \qquad ( 5 )$$
$$50 \geq R ( C ) / R ( D ) \geq 5 , \qquad ( 6 )$$
in the expression (4), MC(5) represents an amount of the silicon-containing polymer C present at a position of 5 nm away from one surface X of the optically anisotropic film in a thickness direction, MC(0) represents an amount of the silicon-containing polymer C present at the surface X, and MC(0) represents a value larger than MC(5),
in the expression (5), MD(5) represents an amount of the silicon-containing polymer D present at a position of 5 nm away from the surface X in the thickness direction, MD(0) represents an amount of the silicon-containing polymer D present at the surface X, and MD(0) represents a value larger than MD(5).

13. The optically anisotropic film according to claim 12,
wherein the silicon-containing polymer D has a repeating unit including, in a side chain, at least one reactive group selected from the group consisting of an acryloyl group, a methacryloyl group, an epoxy group, and a boronic acid group.

14. The optically anisotropic film according to claim 12,
wherein the optically anisotropic film is a positive C-plate or a negative C-plate.

15. The optically anisotropic film according to claim 12,
wherein a content of the silicon-containing polymer C is higher than a content of the silicon-containing polymer D.

16. An optical film comprising:
the optically anisotropic film according to claim 12.

17. A polarizing plate comprising:
the optically anisotropic film according to claim 12; and
a polarizer.

18. An image display apparatus comprising:
the optically anisotropic film according to claim 12.
